(19) United States
(12) Patent Application Publication
(10) Pub. No.: US 2017/0067969 A1
(43) Pub. Date: Mar. 9, 2017

(54) MINIATURIZED MOLECULAR INTERROGATION AND DATA SYSTEM

(71) Applicant: Nativis, Inc., Seattle, WA (US)

(72) Inventors: Bennett M. BUTTERS, Lacey, WA (US); John T. BUTTERS, Langley, WA (US)

(21) Appl. No.: 15/128,938

(22) PCT Filed: Jul. 11, 2013
(86) PCT No.: PCT/US2013/050165

§ 371 Date: Sep. 23, 2016

Related U.S. Application Data
(60) Provisional application No. 61/670,566, filed on Jul. 11, 2012.

(51) Int. Cl. G01R 33/032; G01N 27/72

(52) U.S. Cl. CPC G01R 33/032; G01N 27/72

(57) ABSTRACT

A system for analyzing signals produced from a sample is described, where the system includes at least one magnetometer, where the magnetometer is capable of detecting magnetic fields produced by a sample. The magnetometer is positioned proximate to the sample, and is miniaturized (e.g. has a size less than 6 cm per side). A noise producing component is configured to uniformly produce noise surrounding the sample and the magnetometer, where the noise produced is capable of inducing stochastic resonance in the sample to amplify characteristic signals of the sample. At least one shielding structure electromagnetically shields the sample and the first magnetometer from external electromagnetic radiation

### CROSS-REFERENCE TO RELATED APPLICATION(S)

This application claims priority to U.S. Provisional Patent Application No. 61/670,566, entitled MINIATURIZED MOLECULAR INTERROGATION AND DATA SYSTEM, filed Jul. 11, 2012, which is incorporated herewith in its entirety.

### BACKGROUND

Magnetometers are utilized to measure magnetic field direction and strength in various applications. These devices are included in anything from cars to mobile phones, detecting changes in magnetic field strengths and directions, acting as sensors in devices such as metal detectors, brake systems and compasses. Large scale magnetometers can be utilized in the medical field for nuclear magnetic resonance (NMR) from which machines such as the magnetic resonance imaging (MRI) machine were developed. In the medical and science field, such as within NMR spectrometers, the sensitivity of a magnetometer is extremely important as the magnitude of the magnetic fields of samples are ultra-low and difficult to detect due to high signal-to-noise (SNR) ratios. With some devices, such as the MRI, high relaxivity contrast agents are utilized in order to detect magnetic field variations.

More recent magnetometers providing high sensitivity can employ a superconducting quantum interference device (SQUID). The SQUID is a vector magnetometer having extremely low noise levels. Accordingly, SQUIDs are very useful in measuring very small magnetic field directional components to determine the magnetic field strength.

Recently, another portable magnetometer has been developed. A miniaturized, atom-based magnetic sensor provides even higher sensitivity than the SQUID. This miniaturized device includes a container having rubidium atoms in a gas, a low-power infrared (IR) laser and fiber optics for detecting light signals that register magnetic field strength. Light from the infrared (IR) laser is directed, via the fiber optics, to the container containing the rubidium atoms. The atoms absorb light, and the amount of light absorbed increases as the magnetic field increases. This is because the atoms absorb a photon and enter a higher energy state (energy level) with an increase in the magnetic field. A light detector then detects the amount of light emitted, with a decrease in light detected corresponding to an increase in magnetic field strength. The IR light is known to excite the rubidium atoms in specific states. Thus, the applied magnetic field can be utilized to determine a frequency corresponding to the applied magnetic field which causes the atoms to enter a higher state. An example atomic magnetometer is the spin-exchange relaxation-free (SERF) magnetometer.

Many applications for using these highly sensitive sensors may be possible. For example, the sensor has been used to measure human heart and brain activity. S. Knappe, et al., Cross-validation of a micro-fabricated atomic magnetometers with superconducting quantum interference devices for bio-magnetic applications, Applied Physics Letters 97, 133703 (2010). However, many other applications are possible.

### BRIEF DESCRIPTION OF THE DRAWINGS

FIG. 1 illustrates an isometric view of one embodiment of a molecular electromagnetic signaling detection apparatus formed in accordance with one embodiment of the present invention.

FIG. 2 illustrates an enlarged, detailed view of the Faraday cage and its contents shown in FIG. 1.

FIG. 3 illustrates an enlarged, cross sectional view of one of the attenuation tubes shown in FIGS. 1 and 2.

FIG. 4 illustrates a cross-section view of the Faraday cage and its contents shown in FIG. 2.

FIG. 5 illustrates a diagram of an alternative electromagnetic emission detection system.

FIG. 6 illustrates a diagram of the processing unit included in the detection system of the above Figures.

FIG. 7 illustrates a diagram of an alternative processing unit to that of FIG. 6.

FIG. 8 illustrates a flow diagram of the signal detection and processing performed by the present system.

FIG. 9 illustrates a high-level flow diagram of data flow for the histogram spectral plot method of aspects of the invention;

FIG. 10 illustrates a flow diagram of the algorithm for generating a spectral plot histogram.

FIG. 11 illustrates a flow diagram of steps to identify optimal time-domain signals.

FIG. 12 illustrates a flow diagram of steps to identify optimal time-domain signals in accordance with a third embodiment.

FIG. 13 illustrates the transduction equipment layout in a typical transduction experiment.

FIGS. 13A-13F illustrates schematic diagrams of various coil alignments for use with noise coils.

FIG. 14 illustrates a transduction coil and container used in a typical transduction experiment.

FIG. 15A illustrates a portion of a time-domain signal for a sample containing 40% of an herbicide compound (15A).

FIG. 15B illustrates an FFT of auto-correlated time-domain signals from the sample in 15A, recorded at a noise levels of 70.9-dbm (15B).

FIGS. 15C-D illustrate an FFT of auto-correlated time-domain signals from the sample in 15A, recorded at a noise levels of 74.8-dbm (15C and 15D).

FIG. 15E illustrates an FFT of auto-correlated time-domain signals from the sample in 15A, recorded at a noise levels of 78.3 dbm (15E).

FIG. 15F illustrates a plot of the autocorrelation scores versus the noise setting for the sample in FIG. 15.

FIG. 16 illustrates a block diagram of a process for creating a signal from a sample applied to a biological system.

FIG. 17 illustrates a block diagram of a suitable system for applying electromagnetic waves generated from signals created from a sample under the inventive system to a patient.

FIG. 18 illustrates a flow diagram of a signal processing routine for modifying one or more starting waveforms.

FIGS. 19A-19D illustrate modifications of a spectral plot using a graphical user interface (GUI).

FIG. 20 illustrates a block diagram for alternatives in distributing a signal generated and processed by the detection system and processing unit.

FIG. 21 illustrates a block diagram of a transducer-receiver/transceiver for the distribution system of FIG. 20.

FIG. 22 illustrates a Helmholtz-type induction coil for use within the system of FIG. 20.

FIG. 23 illustrates an implantable coil for transducing a sample.

FIG. 24 illustrates a diagram of a miniature atomic magnetometer-based molecular interrogation and data system (MIDS).

FIG. 25 illustrates a block diagram of additional components for use with the miniature MIDS system of FIG. 24.

FIG. 26 illustrates a schematic diagram of a coil alignment system for pivoting and telescoping a noise coil.

FIG. 27 illustrates a diagram of an optical magnetometer flow-thru device for molecular interrogation.

The headings provided herein are for convenience only and do not necessarily affect the scope or meaning of the claimed invention.

### DETAILED DESCRIPTION

Described in detail below is a miniaturized detector for detecting very low amplitude signals to produce time-domain signals by recording a signal produced by a sample or compound in a shielded environment, while injecting a Gaussian white noise stimulus into the recording apparatus at a level that enhances the ability to observe low-frequency stochastic events produced by the compound. In commonly owned U.S. Provisional applications 60/593,006 and 60/591,549, further noted below, the transducing signal was the actual compound time-domain signal of an effector compound.

The possibility of achieving effector-molecule functions by exposing a target system to characteristic effector-molecule signals, without the need for the actual presence of the effector agent, has a number of important and intriguing applications. Instead of treating an organism by the application of a drug, the same effect may be achieved by exposing the organism to drug-specific signals. In the field of nanofabrication, it may now be possible to catalyze or encourage self-assembly patterns by introducing in the assembly system, signals characteristic of multivalent effector molecules capable of promoting the desired pattern of self-assembly.

An apparatus and method for detecting the low level frequencies produced by biological samples through use of highly sensitive, yet miniaturized magnetometers is described in detail below. Apparatuses and methods for detecting, processing, and presenting low frequency electromagnetic emissions or signals of a sample of interest are provided where, in one embodiment, a known uniform white or Gaussian noise signal is introduced to the sample. The noise is configured to permit the electromagnetic emissions from the sample to be sufficiently detected by a signal detection system. Sets of detected signals are processed together to ensure repeatability and statistical relevance. The resulting emission pattern or spectrum can be displayed, stored, and/or identified as a particular substance.

Additional embodiments of the present invention describe signals for use with a transducing system for producing compound-specific electromagnetic waves that can act on target systems placed in the field of the waves and the corresponding methods of producing such signals. Other embodiments relate to generating and distributing such signals.

Various examples of the invention will now be described. The following description provides certain specific details for a thorough understanding and enabling description of these examples. One skilled in the relevant technology will understand, however, that the invention may be practiced without many of these details. Likewise, one skilled in the relevant technology will also understand that the invention may include many other obvious features not described in detail herein. Additionally, some well-known structures or functions may not be shown or described in detail below, to avoid unnecessarily obscuring the relevant descriptions of the various examples.

The terminology used below is to be interpreted in its broadest reasonable manner, even though it is being used in conjunction with a detailed description of certain specific examples of the invention. Indeed, certain terms may even be emphasized below; however, any terminology intended to be interpreted in any restricted manner will be overtly and specifically defined as such in this Detailed Description section.

The application is organized as follows, First some definitions are provided. Second, the inventors' earlier SQUID-based system is described to provide, in part, an understanding of basic signal acquisition. Third, methods of producing an optimized time-domain signal, and for forming transducing signals are discussed. Fourth, certain transduction apparatus and protocols are provided. Finally, the miniaturized detector or miniaturized molecular interrogation and data system is discussed in detail. Those of ordinary skill in the relevant art will recognize that aspects of the SQUID-based system, aspects of the methods for producing informing signals, and aspects of the transduction apparatus and protocols may individually or collectively be applied to the miniaturized detector to provide yet further embodiments of the invention that allow signal acquisition and use by the miniaturized detector.

### I. DEFINITIONS

The terms below have the following definitions unless indicated otherwise. Such definitions, although brief, will help those skilled in the relevant art to more fully appreciate aspects of the invention based on the detailed description provided herein. Such definitions are further defined by the description of the invention as a whole (including the claims) and not simply by such definitions.

“Magnetic shielding” refers to shielding that decreases, inhibits or prevents passage of magnetic flux as a result of the magnetic permeability of the shielding material.

“Electromagnetic shielding” refers to, e.g., standard Faraday electromagnetic shielding, or other methods to reduce passage of electromagnetic radiation.

“Time-domain signal” or ‘time-series signal” refers to a signal with transient signal properties that change over time.

“Sample-source radiation” refers to magnetic flux or electromagnetic flux emissions resulting from molecular motion of a sample, such as the rotation of a molecular dipole in a magnetic field. Because sample source radiation is produced in the presence of an injected magnetic-field stimulus,” it is also referred to as “sample source radiation superimposed on injected magnetic field stimulus.”

“Stimulus magnetic field” or “Magnetic-field stimulus” refers to a magnetic field produced by injecting (applying) to magnetic coils surrounding a sample, one of a number of electromagnetic signals that may include (i) white noise, injected at voltage level calculated to produce, a selected magnetic field at the sample of between 0 and 1 G (Gauss), (ii) a DC offset, injected at voltage level calculated to produce a selected magnetic field at the sample of between 0 and 1 G, and (iii) sweeps over a low-frequency range, injected successively over a sweep range between at least about 0-1 kHz, and at an injected voltage calculated to produce a selected magnetic field at the sample of between 0 and 1 G. The magnetic field produced at the sample may be readily calculated using known electromagnetic relationships, knowing the shape and number of windings in the injection coil, the voltage applied to coils, and the distance between the injection coils and the sample.

A “selected stimulus magnetic-field condition” refers to a selected voltage applied to a white noise or DC offset signal, or a selected sweep range, sweep frequency and voltage of an applied sweep stimulus magnetic field.

“White noise” refers to random noise or a signal having simultaneous multiple frequencies, e.g., white random noise or deterministic noise. Several variations of white noise and other noise may be utilized in the embodiments described in the present invention. For example, “Gaussian white noise” is white noise having a Gaussian power distribution. “Stationary Gaussian white noise” is random Gaussian white noise that has no predictable future components. “Structured noise” is white noise that may contain a logarithmic characteristic which shifts energy from one region of the spectrum to another, or it may be designed to provide a random time element while the amplitude remains constant. These two represent pink and uniform noise, as compared to truly random noise which has no predictable future component. “Uniform noise” means white noise having a rectangular distribution rather than a Gaussian distribution.

“Frequency-domain spectrum” refers to a Fourier frequency plot of a time-domain signal.

“Spectral components” refers to singular or repeating qualities within a time-domain signal that can be measured in the frequency, amplitude, and/or phase domains. Spectral components will typically refer to signals present in the frequency domain.

“Faraday cage” refers to an electromagnetic shielding configuration that provides an electrical path to ground for unwanted electromagnetic radiation, thereby quieting an electromagnetic environment.

### II. APPARATUS FOR PRODUCING AND PROCESSING TIME-DOMAIN SIGNALS

Embodiments of the present invention provide a method and apparatus for detecting extremely low-threshold molecular electromagnetic signals without external interference. They further provide for the output of those signals in a format readily usable by a wide variety of signal recording and processing equipment. Accordingly, embodiments of the present invention are directed to providing an apparatus and method for the repeatable detection and recording of low-threshold molecular electromagnetic signals. A magnetically shielded Faraday cage shields the sample material and detection apparatus from extraneous electromagnetic signals. Within the magnetically shielded Faraday cage, a coil injects uniform or white noise, a nonferrous tray holds the sample, and a gradiometer detects low-threshold molecular electromagnetic signals. The apparatus further includes a superconducting quantum interference device (“SQUID”) and a preamplifier.

The apparatus is utilized by placing a sample within the magnetically shielded Faraday cage in close proximity to the noise coil and gradiometer. White noise is injected through the noise coil and modulated until the molecular electromagnetic signal is enhanced through stochastic resonance. The enhanced molecular electromagnetic signal, shielded from external interference by the Faraday cage and the field generated by the noise coil, is then detected and measured by the gradiometer and SQUID. The signal is then amplified and transmitted to any appropriate recording or measuring equipment.

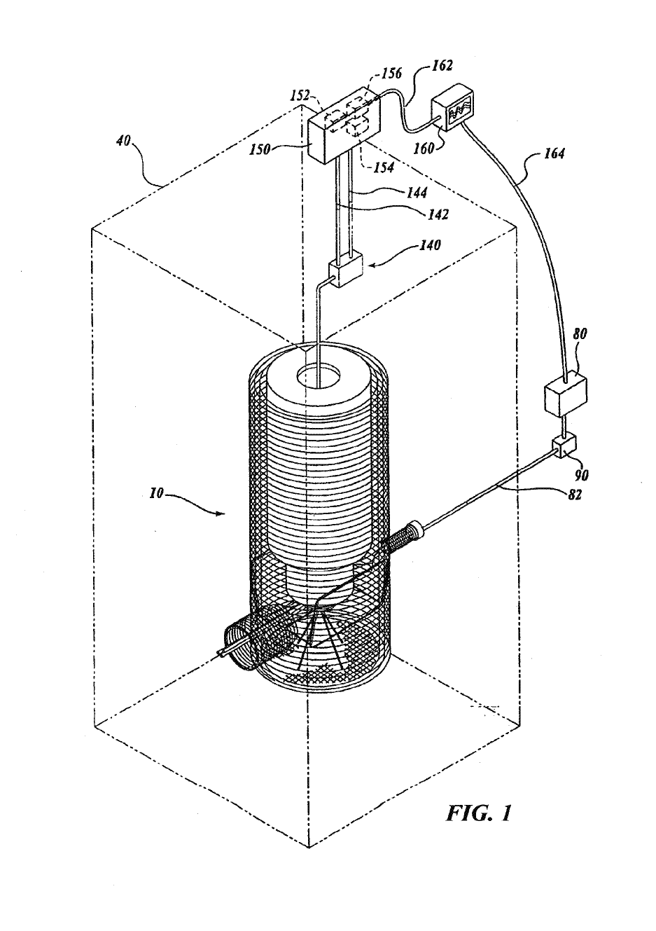

FIGS. 1-5 provide various views of the apparatus described in the previous paragraphs. The apparatus illustrated provides one embodiment of the invention, though additional embodiments are described and contemplated within the scope of the invention.

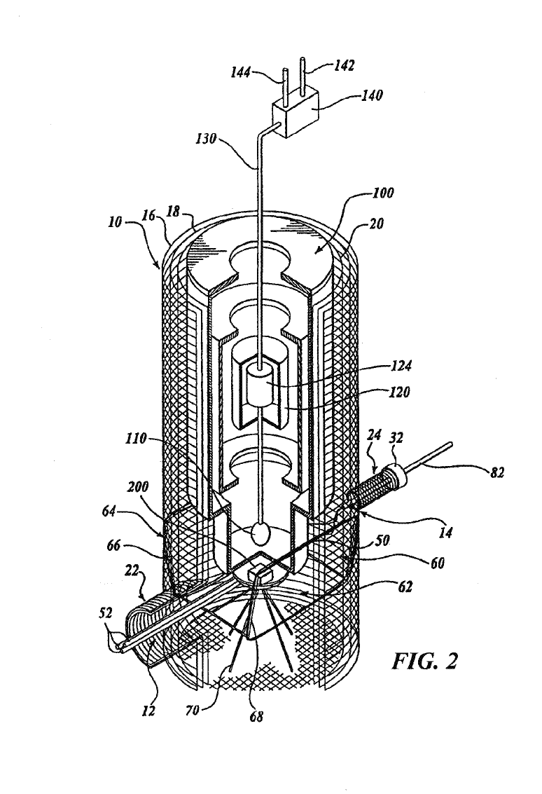

Referring to FIG. 1, an amplitude adjustable white noise generator 80 is external to magnetic shielding cage 40, and is electrically connected to a Helmholtz transformer 60 (not shown) through filter 90 by electrical cable 82. The Helmholtz coil, or transformer 60, is illustrated and further described with reference to FIG. 2. The white noise generator 80 can generate nearly uniform noise across a frequency spectrum from zero to 100 kilohertz. In the illustrated embodiment, the filter 90 filters out noise above 50 kilohertz, but other frequency ranges may be used. White noise generator 80 is also electrically connected to the other input of dual trace oscilloscope 160 through patch cord 164.

A Flux Locked Loop 140 further amplifies and outputs a signal received from a SQUID 120 via high-level output circuit 142 to an iMC-303 IMAGO SQUID controller 150. The SQUID is further described with reference to FIG. 2 in the following paragraphs. The Flux-Locked Loop 140 is also connected via a model CC-60 six-meter fiber-optic composite connecting cable 144 to the SQUID controller 150. The fiber-optic connecting cable 144 and SQUID controller 150 are manufactured by Tristan Technologies, Inc. The controller 150 is mounted externally to the magnetic shielding cage 40. The fiber-optic connecting cable 144 carriers control signals from the SQUID controller 150 to the Flux Locked Loop 140, further reducing the possibility of electromagnetic interference with the signal to be measured. It will be apparent to those skilled in the art that other Flux-Locked Loops, connecting cables, and Squid controllers can be used.

The SQUID controller 150 further comprises high resolution analog to digital converters 152, a standard GP-IB bus 154 to output digitalized signals, and BNC connectors 156 to output analog signals. In the illustrated embodiment, the BNC connectors are connected to a dual trace oscilloscope 160 through patch cord 162.

Referring now to FIG. 2 a cross-sectional view of the elements within the a shielding structure 10 in FIG. 1 is illustrated. The shielding structure 10 includes, in an outer to inner direction, a conductive wire cage 16, which is a magnetic shield, and inner conductive wire cages 18 and 20, which provide electromagnetic shielding. In another embodiment, the outer magnetic shield 16 is formed of a solid aluminum plate material having an aluminum-nickel alloy coating, and the electromagnetic shielding is provided by two inner wall structures, each formed of solid aluminum.

As illustrated in FIG. 2, the shielding structure, which can be a Faraday cage 10 is open at the top, and includes side openings 12 and 14. The Faraday cage 10 is further comprised of three copper mesh cages 16, 18 and 20, nestled in one another. Each of the copper mesh cages 16, 18 and 20 is electrically isolated from the other cages by dielectric barriers (not shown) between each cage.

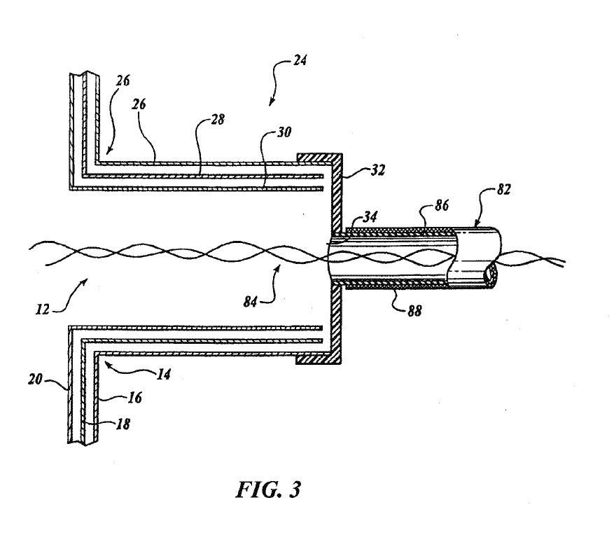

Side openings 12 and 14 further comprise attenuation tubes 22 and 24 to provide access to the interior of the Faraday cage 10 while isolating the interior of the cage from external sources of interference. Referring to FIG. 3, attenuation tube 24 is comprised of three copper mesh tubes 26, 28 and 30, nestled in one another. The exterior copper mesh cages 16, 18 and 20 are each electrically connected to one of the copper mesh tubes 26, 28 and 30, respectively. Attenuation tube 24 is further capped with cap 32 and the cap may further include a hole 34. Attenuation tube 22 is similarly comprised of copper mesh tubes 26, 28 and 30, but does not include cap 32.

A low-density nonferrous sample tray 50 is mounted in the interior of the Faraday cage 10. The sample tray 50 is mounted so that it may be removed from the Faraday cage 10 through the attenuation tube 22 and side opening 12. Three rods 52, each of which is greater in length than the distance from the center vertical axis of the Faraday cage 10 to the outermost edge of the attenuation tube 22, are attached to the sample tray 50. The three rods 52 are adapted to conform to the interior curve of the attenuation tube 22, so that the sample tray 50 may be positioned in the center of the Faraday cage 10 by resting the rods in the attenuation tube. In the illustrated embodiment, the sample tray 50 and rods 52 are made of glass fiber epoxy. It will be readily apparent to those skilled in the art that the sample tray 50 and rods 52 may be made of other nonferrous materials, and the tray may be mounted in the Faraday cage 10 by other means, such as by a single rod.

Mounted within the Faraday cage 10 and above the sample tray 50 is a cryogenic dewar 100. In the disclosed embodiment, the dewar 100 is adapted to fit within the opening at the top of Faraday cage 10 and is a Model BMD-6 Liquid Helium Dewar manufactured by Tristan Technologies, Inc. The dewar 100 is constructed of a glass-fiber epoxy composite. A gradiometer 110 with a very narrow field of view is mounted within the dewar 100 in position so that its field of view encompasses the sample tray 50. In the illustrated embodiment, the gradiometer 110 is a first order axial detection coil, nominally 1 centimeter in diameter, with a 2% balance, and is formed from a superconductor. The gradiometer can be any form of gradiometer excluding a planar gradiometer. The gradiometer 110 is connected to the input coil of one low temperature direct current superconducting quantum interference device (“SQUID”) 120. In the disclosed embodiment, the SQUID is a Model LSQ/20 LTS dc SQUID manufactured by Tristan Technologies, Inc. It will be recognized by those skilled in the art that high temperature or alternating current SQUIDs can be used. In an alternative embodiment, the SQUID 120 includes a noise suppression coil 124. The disclosed combination of gradiometer 110 and SQUID 120 have a sensitivity of 5 microTesla/√Hz when measuring magnetic fields.

The output of SQUID 120 is connected to a Model SP Cryogenic Cable 130 manufactured by Tristan Technologies, Inc. The Cryogenic Cable 130 is capable of withstanding the temperatures within and without the dewar 100 and transfers the signal from the SQUID 120 to Flux-Locked Loop 140, which is mounted externally to the Faraday cage 10 and dewar 100. The Flux-Locked Loop 140 in the disclosed embodiment is an iFL-301-L Flux Locked Loop manufactured by Tristan Technologies, Inc.

Referring still to FIG. 2, a two-element Helmholtz transformer 60 is installed to either side of the sample tray 50 when the sample tray is fully inserted within the Faraday cage 10. In the illustrated embodiment, the coil windings 62 and 64 of the Helmholtz transformer 60 are designed to operate in the direct current to 50 kilohertz range, with a center frequency of 25 kilohertz and self-resonant frequency of 8.8 megahertz. In the illustrated embodiment, the coil windings 62 and 64 are generally rectangular in shape and are approximately 8 inches tall by 4 inches wide. Other Helmholtz coil shapes may be used but should be shaped and sized so that the gradiometer 110 and sample tray 50 are positioned within the field produced by the Helmholtz coil. Each of coil windings 62 and 64 is mounted on one of two low-density nonferrous frames 66 and 68. The frames 66 and 68 are hingedly connected to one another and are supported by legs 70. Frames 66 and 68 are slidably attached to legs 70 to permit vertical movement of the frames in relation to the lower portion of dewar 100. Movement of the frames permits adjustment of the coil windings 62 and 64 of the Helmholtz transformer 60 to vary the amplitude of white noise received at gradiometer 110. The legs 70 rest on or are epoxied onto the bottom of the Faraday cage 10. In the illustrated embodiment, the frames 66 and 68 and legs 70 are made of glass fiber epoxy. Other arrangements of transformers or coils may be used around the sample tray 50.

Referring now to FIG. 3, cable 82 is run through side opening 12, attenuation tube 24, and through cap 32 via hole 34. Cable 82 is a co-axial cable further comprising a twisted pair of copper conductors 84 surrounded by interior and exterior magnetic shielding 86 and 88, respectively. In other embodiments, the conductors can be any nonmagnetic electrically conductive material, such as silver or gold. The interior and exterior magnetic shielding 86 and 88 terminates at cap 32, leaving the twisted pair 84 to span the remaining distance from the end cap to the Helmholtz transformer 60 shown in FIG. 1. The interior magnetic shielding 86 is electrically connected to Faraday cage 16 through cap 32, while the exterior magnetic shielding is electrically connected to the magnetically shielded cage 40 shown in FIG. 1.

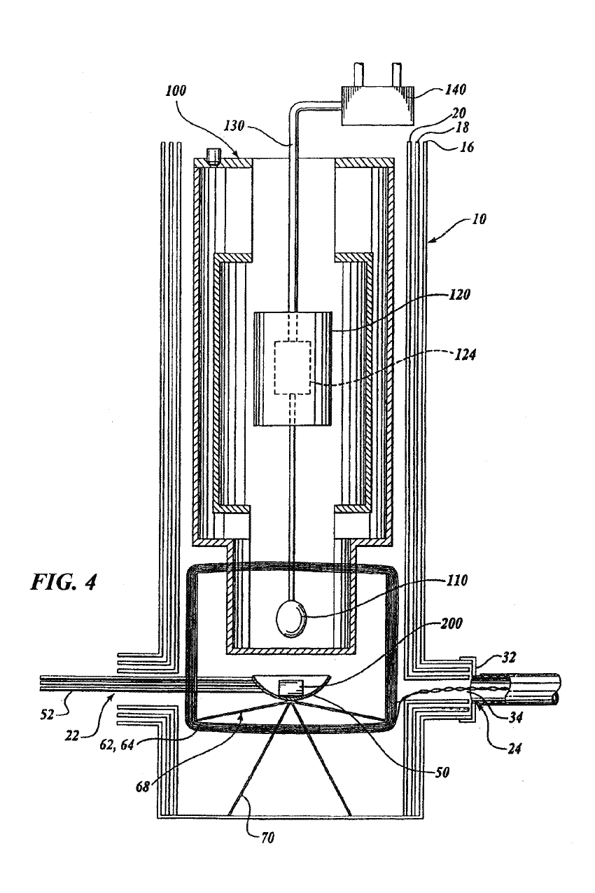

Referring now to FIG. 4, a cross-sectional view of the Faraday cage and its contents is further illustrated. The cage shows windings 62 of Helmholtz transformer 60 in relation to dewar 100 and Faraday cage 10.

Referring to FIGS. 1-4, an exemplary embodiment is now described. A sample of the substance 200 to be measured is placed on the sample tray 50 and the sample tray is placed within the Faraday cage 10. In the first embodiment, the white noise generator 80 is used to inject white noise through the Helmholtz transformer 60. The noise signal creates an induced voltage in the gradiometer 110. The induced voltage in the gradiometer 110 is then detected and amplified by the SQUID 120, the output from the SQUID is further amplified by the flux locked loop 140 and sent to the SQUID controller 150, and then sent to the dual trace oscilloscope 160. The dual trace oscilloscope 160 is also used to display the signal generated by white noise generator 80.

The white noise signal is adjusted by altering the output of the white noise generator 80 and by rotating the Helmholtz transformer 60 around the sample 200, shown in FIG. 2. Rotation of the Helmholtz transformer 60 about the axis of the hinged connection of frames 66 and 68 alters its phasing with respect to the gradiometer 110. Depending upon the desired phase alteration, the hinged connection of frames 66 and 68 permits windings 62 and 64 to remain parallel to one another while rotating approximately 30 to 40 degrees around sample tray 50. The hinged connection also permits windings 62 and 64 to rotate as much as approximately 60 degrees out of parallel, in order to alter signal phasing of the field generated by Helmholtz transformer 60 with respect to gradiometer 110.

The typical adjustment of phase will include this out-of-parallel orientation, although the other orientation may be preferred in certain circumstances, to accommodate an irregularly shaped sample 200, for example. Noise is applied and adjusted until the noise is 30 to 35 decibels above the molecular electromagnetic emissions sought to be detected. At this noise level, the noise takes on the characteristics of the molecular electromagnetic signal through the well-known phenomenon of stochastic resonance. The stochastic product sought is observed when the oscilloscope trace reflecting the signal detected by gradiometer 110 varies from the trace reflecting the signal directly from white noise generator 80. In alternative embodiments, the signal can be recorded and or processed by any commercially available equipment.

In an alternative embodiment, the method of detecting the molecular electromagnetic signals further comprises injecting noise 180° out of phase with the original noise signal applied at the Helmholtz transformer 60 through the noise suppression coil 124 of the SQUID 120. The stochastic product sought can then be observed when the oscilloscope trace reflecting the signal detected by gradiometer 110 becomes non-random.

Regardless of how the noise is injected and adjusted, the stochastic product can also be determined by observing when an increase in spectral peaks occurs. The spectral peaks can be observed as either a line plot on oscilloscope 160 or as numerical values, or by other well-known measuring devices.

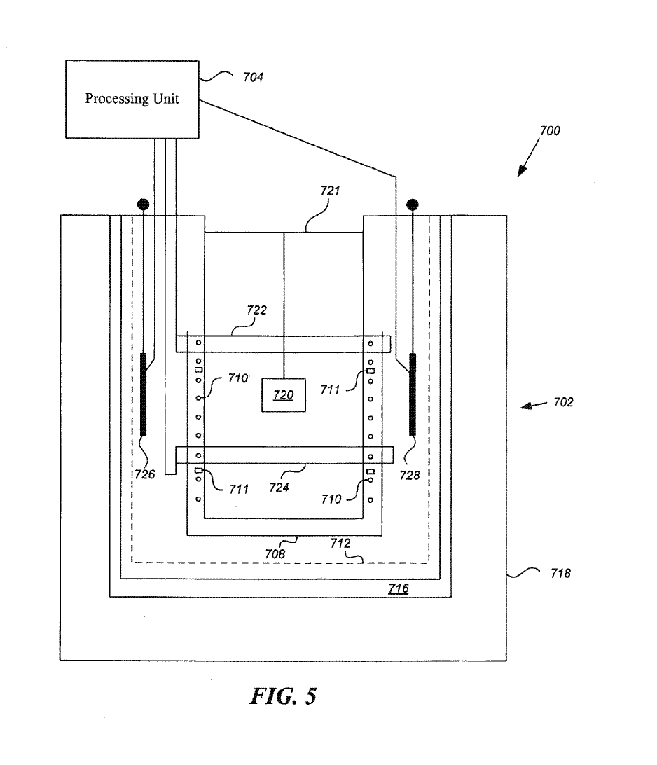

Referring now to FIG. 5, an alternative embodiment to the molecular electromagnetic emission detection and processing system of the above Figures is shown. A system 700 includes a detection unit 702 coupled to a processing unit 704. Although the processing unit 704 is shown external to the detection unit 702, at least a part of the processing unit can be located within the detection unit.

The detection unit 702, which is shown in a cross-sectional view in FIG. 5, includes multiple components nested or concentric with each other. A sample chamber or Faraday cage 706 is nested within a metal cage 708. Each of the sample chamber 706 and the metal cage 708 can be comprised of aluminum material. The sample chamber 706 can be maintained in a vacuum and may be temperature controlled to a preset temperature. The metal cage 708 is configured to function as a low pass filter.

Between the sample chamber 706 and the metal cage 708 and encircling the sample chamber 706 are a set of parallel heating coils or elements 710. One or more temperature sensor 711 is also located proximate to the heating elements 710 and the sample chamber 706. For example, four temperature sensors may be positioned at different locations around the exterior of the sample chamber 706. The heating elements 710 and the temperature sensor(s) 711 may be configured to maintain a certain temperature inside the sample chamber 706.

A shield 712 encircles the metal cage 708. The shield 712 is configured to provide additional magnetic field shielding or isolation for the sample chamber 706. The shield 712 can be comprised of lead or other magnetic shielding materials. The shield 712 is optional when sufficient shielding is provided by the sample chamber 706 and/or the metal cage 708.

Surrounding the shield 712 is a cryogen layer 716 with G10 insulation. The cryogen may be liquid helium. The cryogen layer 716 (also referred to as a cryogenic Dewar) is at an operating temperature of 4 degrees Kelvin. Surrounding the cryogen layer 716 is an outer shield 718. The outer shield 718 is comprised of nickel alloy and is configured to be a magnetic shield. The total amount of magnetic shielding provided by the detection unit 702 is approximately −100 dB, −100 dB, and −120 dB along the three orthogonal planes of a Cartesian coordinate system.

The various elements described above are electrically isolated from each other by air gaps or dielectric barriers (not shown). It should also be understood that the elements are not shown to scale relative to each other for ease of description.

A sample holder 720 can be manually or mechanically positioned within the sample chamber 706. The sample holder 720 may be lowered, raised, or removed from the top of the sample chamber 706. The sample holder 720 is comprised of a material that will not introduce Eddy currents and exhibits little or no inherent molecular rotation. As an example, the sample holder 720 can be comprised of high quality glass or Pyrex.

The detection unit 702 is configured to handle solid, liquid, or gas samples. Various sample holders may be utilized in the detection unit 702. For example, depending on the size of the sample, a larger sample holder may be utilized. As another example, when the sample is reactive to air, the sample holder can be configured to encapsulate or form an airtight seal around the sample. In still another example, when the sample is in a gaseous state, the sample can be introduced inside the sample chamber 706 without the sample holder 720. For such samples, the sample chamber 706 is held at a vacuum. A vacuum seal 721 at the top of the sample chamber 706 aids in maintaining a vacuum and/or accommodating the sample holder 720.

A sense coil 722 and a sense coil 724, also referred to as detection coils, are provided above and below the sample holder 720, respectively. The coil windings of the sense coils 722, 724 are configured to operate in the direct current (DC) to approximately 50 kilohertz (kHz) range, with a center frequency of 25 kHz and a self-resonant frequency of 8.8 MHz. The sense coils 722, 724 are in the second derivative form and are configured to achieve approximately 100% coupling. In one embodiment, the coils 722, 724 are generally rectangular in shape and are held in place by G10 fasteners. The coils 722, 724 function as a second derivative gradiometer.

Helmholtz coils 726 and 728 may be vertically positioned between the shield 712 and the metal cage 708, as explained herein. Each of the coils 726 and 728 may be raised or lowered independently of each other. The coils 726 and 728, also referred to as a white or Gaussian noise generation coils, are at room or ambient temperature. The noise generated by the coils 726, 728 is approximately 0.10 Gauss.

The degree of coupling between the emissions from the sample and the coils 722, 724 may be changed by repositioning the sample holder 720 relative to the coils 722, 724, or by repositioning one or both of the coils 726, 728 relative to the sample holder 720.

The processing unit 704 is electrically coupled to the coils 722, 724, 726, and 728. The processing unit 704 specifies the white or Gaussian noise to be injected by the coils 726, 728 to the sample. The processing unit 104 also receives the induced voltage at the coils 722, 724 from the sample's electromagnetic emissions mixed with the injected Gaussian noise.

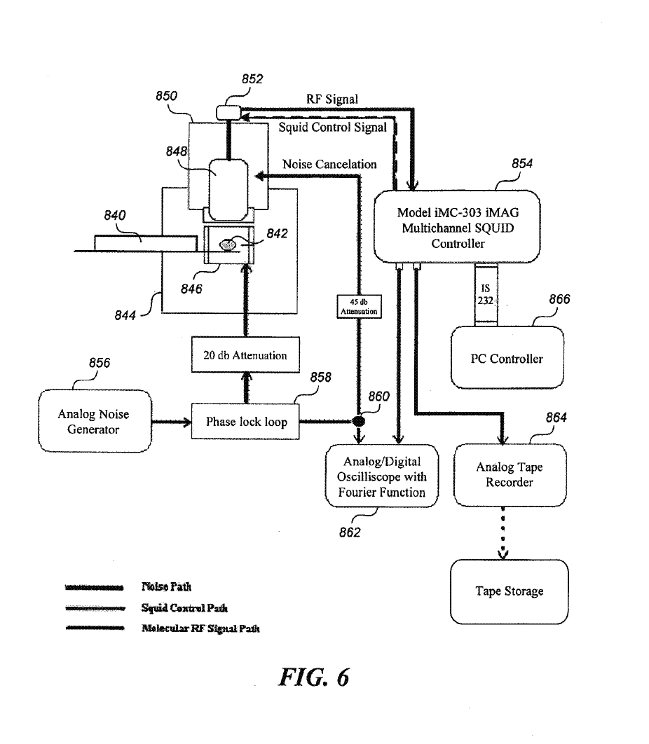

Referring to FIG. 6, a processing unit employing aspects of the invention includes a sample tray 840 that permits a sample 842 to be inserted into, and removed from, a Faraday cage 844 and Helmholtz coil 746. A SQUID/gradiometer detector assembly 848 is positioned within a cryogenic dewar 850. A flux-locked loop 852 is coupled between the SQUID/gradiometer detector assembly 848 and a SQUID controller 854. The SQUID controller 854 may be a model iMC-303 iMAG multichannel controller provided by Tristan.

An analog noise generator 856 provides a noise signal (as noted above) to a phase lock loop 858. The x-axis output of the phase lock loop is provided to the Helmholtz coil 846, and may be attenuated, such as by 20 dB. The y-axis output of the phase lock loop is split by a signal splitter 860. One portion of the y-axis output is input the noise cancellation coil at the SQUID, which has a separate input for the gradiometer. The other portion of the y-axis signal is input oscilloscope 862, such as an analog/digital oscilloscope having Fourier functions like the Tektronix TDS 3000b (e.g., model 3032b). That is, the x-axis output of the phase lock loop drives the Helmholtz coil, and the y-axis output, which is in inverted form, is split to input the SQUID and the oscilloscope. Thus, the phase lock loop functions as a signal inverter. The oscilloscope trace is used to monitor the analog noise signal, for example, for determining when a sufficient level of noise for producing non-stationary spectral components is achieved. An analog tape recorder or recording device 864, coupled to the controller 854, records signals output from the device, and is preferably a wideband (e.g. 50 kHz) recorder. A PC controller 866 may be an MS Windows based PC interfacing with the controller 854 via, for example, an RS 232 port.

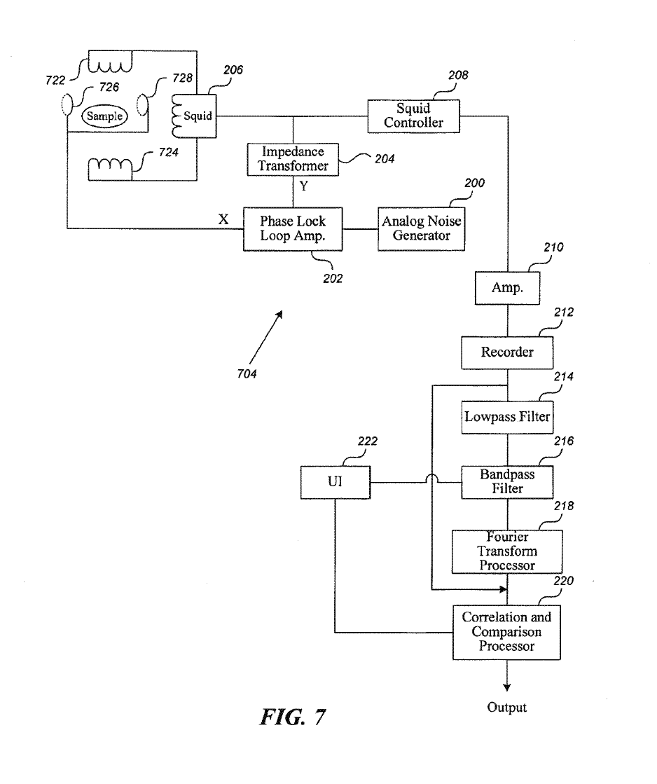

In FIG. 7, a block diagram of another embodiment of the processing unit is shown. A dual phase lock-in amplifier 202 is configured to provide a first signal (e.g., “x” or noise signal) to the coils 726, 728 and a second signal (e.g., “y” or noise cancellation signal) to a noise cancellation coil of a superconducting quantum interference device (SQUID) 206. The amplifier 202 is configured to lock without an external reference and may be a Perkins Elmer model 7265 DSP lock-in amplifier. This amplifier works in a “virtual mode,” where it locks to an initial reference frequency, and then removes the reference frequency to allow it to run freely and lock to “noise.”

An analog noise generator 200 is electrically coupled to the amplifier 202. The generator 200 is configured to generate or induce an analog white Gaussian noise at the coils 726, 728 via the amplifier 202. As an example, the generator 200 may be a model 1380 manufactured by General Radio.

An impedance transformer 204 is electrically coupled between the SQUID 206 and the amplifier 202. The impedance transformer 204 is configured to provide impedance matching between the SQUID 206 and amplifier 202.

The noise cancellation feature of the SQUID 206 can be turned on or off. When the noise cancellation feature is turned on, the SQUID 206 is capable of canceling or nullifying the injected noise component from the detected emissions. To provide the noise cancellation, the first signal to the coils 726, 728 is a noise signal at 20 dB or 35 dB above the molecular electromagnetic emissions sought to be detected. At this level, the injected noise takes on the characteristics of the molecular electromagnetic signal through stochastic resonance. The second signal to the SQUID 206 is a noise cancellation signal and is inverted from the first signal at an amplitude sufficient to null the noise at the SQUID output (e.g., 180 degrees out of phase with respect to the first signal).

The SQUID 206 is a low temperature direct element SQUID. As an example, the SQUID 206 may be a model LSQ/20 LTS dC SQUID manufactured by Tristan Technologies, Inc. Alternatively, a high temperature or alternating current SQUID can be used. The coils 722, 724 (e.g., gradiometer) and the SQUID 206 (collectively referred to as the SQUID/gradiometer detector assembly) combined has a magnetic field measuring sensitivity of approximately 5 microTesla/√Hz. The induced voltage in the coils 722, 724 is detected and amplified by the SQUID 206. The output of the SQUID 206 is a voltage approximately in the range of 0.2-0.8 microVolts.

The output of the SQUID 206 is the input to a SQUID controller 208. The SQUID controller 208 is configured to control the operational state of the SQUID 206 and further condition the detected signal. As an example, the SQUID controller 208 may be an iMC-303 iMAG multi-channel SQUID controller manufactured by Tristan Technologies, Inc.

The output of the SQUID controller 208 is inputted to an amplifier 210. The amplifier 210 is configured to provide a gain in the range of 0-100 dB. A gain of approximately 20 dB is provided when noise cancellation node is turned on at the SQUID 206. A gain of approximately 50 dB is provided when the SQUID 206 is providing no noise cancellation.

The amplified signal is inputted to a recorder or storage device 212. The recorder 212 is configured to convert the analog amplified signal to a digital signal and store the digital signal. In one embodiment, the recorder 212 stores 8600 data points per Hz and can handle 2.46 Mbits/sec. As an example, the recorder 212 may be a Sony digital audiotape (DAT) recorder. Using a DAT recorder, the raw signals or data sets can be sent to a third party for display or specific processing as desired.

A lowpass filter 214 filters the digitized data set from the recorder 212. The lowpass filter 214 is an analog filter and may be a Butterworth filter. The cutoff frequency is at approximately 50 kHz.

A bandpass filter 216 next filters the filtered data sets. The bandpass filter 216 is configured to be a digital filter with a bandwidth between DC to 50 kHz. The bandpass filter 216 can be adjusted for different bandwidths.

The output of the bandpass filter 216 is the input to a Fourier transformer processor 218. The Fourier transform processor 218 is configured to convert the data set, which is in the time domain, to a data set in the frequency domain. The Fourier transform processor 218 performs a Fast Fourier Transform (FFT) type of transform.

The Fourier transformed data sets are the input to a correlation and comparison processor 220. The output of the recorder 212 is also an input to the processor 220. The processor 220 is configured to correlate the data set with previously recorded data sets, determine thresholds, and perform noise cancellation (when no noise cancellation is provided by the SQUID 206). The output of the processor 220 is a final data set representative of the spectrum of the sample's molecular low frequency electromagnetic emissions.

A user interface (UI) 222, such as a graphical user interface (GUI), may also be connected to at least the filter 216 and the processor 220 to specify signal processing parameters. The filter 216, processor 218, and the processor 220 can be implemented as hardware, software, or firmware. For example, the filter 216 and the processor 218 may be implemented in one or more semiconductor chips. The processor 220 may be software implemented in a computing device.

This amplifier works in a “virtual mode,” where it locks to an initial reference frequency, and then removes the reference frequency to allow it to run freely and lock to “noise.” The analog noise generator (which is produced by General Radio, a truly analog noise generator) requires 20 dB and 45-dB attenuation for the Helmholtz and noise cancellation coil, respectively.

The Helmholtz coil may have a sweet spot of about one cubic inch with a balance of 1/100^{th} of a percent. In an alternative embodiments, the Helmholtz coil may move both vertically, rotationally (about the vertical access), and from a parallel to spread apart in a pie shape. In one embodiment, the SQUID, gradiometer, and driving transformer (controller) have values of 1.8, 1.5 and 0.3 micro-Henrys, respectively. The Helmholtz coil may have a sensitivity of 0.5 Gauss per amp at the sweet spot.

Approximately 10 to 15 microvolts may be needed for a stochastic response. By injecting noise, the system has raised the sensitivity of the SQUID device. The SQUID device had a sensitivity of about 5 femtotesla without the noise. This system has been able to improve the sensitivity by 25 to 35 dB by injecting noise and using this stochastic resonance response, which amounts to nearly a 1,500% increase.

After receiving and recording signals from the system, a computer, such as a mainframe computer, supercomputer or high-performance computer does both pre and post processing, such by employing the Autosignal software product by Systat Software of Richmond Calif., for the pre-processing, while Flexpro software product does the post-processing. Flexpro is a data (statistical) analysis software supplied by Dewetron, Inc. The following equations or options may be used in the Autosignal and Flexpro products.

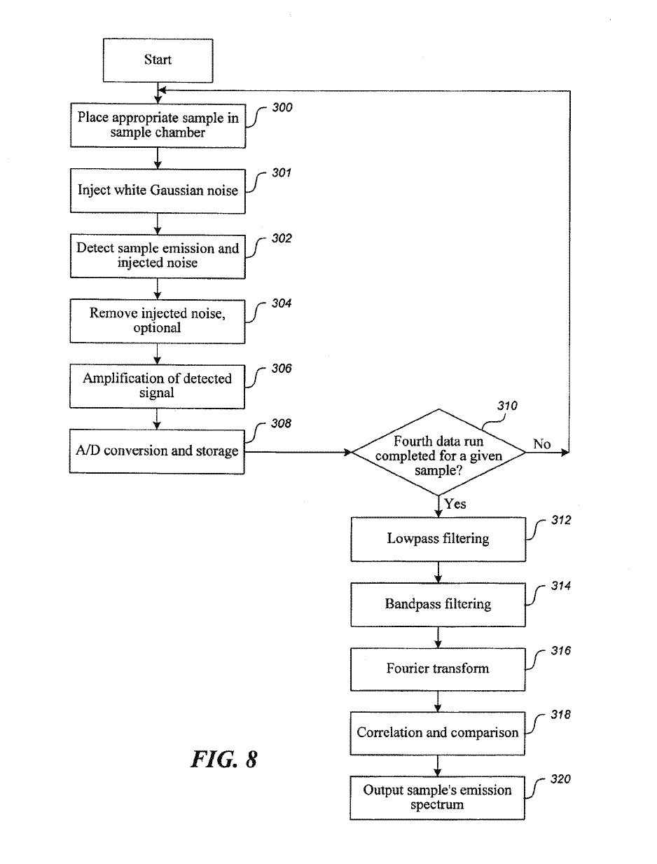

“′A flow diagram of the signal detection and processing performed by the system 100 is shown in FIG. 8. When a sample is of interest, at least four signal detections or data runs are performed: a first data run at a time t₁ without the sample, a second data run at a time t₂ with the sample, a third data run at a time t₃ with the sample, and a fourth data run at a time t4 without the sample. Performing and collecting data sets from more than one data run increases accuracy of the final (e.g., correlated) data set. In the four data runs, the parameters and conditions of the system 100 are held constant (e.g., temperature, amount of amplification, position of the coils, the noise signal, etc.).

At a block 300, the appropriate sample (or if it's a first or fourth data run, no sample), is placed in the system 100. A given sample, without injected noise, emits electromagnetic emissions in the DC-50 kHz range at an amplitude equal to or less than approximately 0.001 microTesla. To capture such low emissions, a white Gaussian noise is injected at a block 301.

At a block 302, the coils 722, 724 detect the induced voltage representative of the sample's emission and the injected noise. The induced voltage comprises a continuous stream of voltage values (amplitude and phase) as a function of time for the duration of a data run. A data run can be 2-20 minutes in length and hence, the data set corresponding to the data run comprises 2-20 minutes of voltage values as a function of time.

At a block 304, the injected noise is cancelled as the induced voltage is being detected. This block is omitted when the noise cancellation feature of the SQUID 206 is turned off.

At a block 306, the voltage values of the data set are amplified by 20-50 dB, depending on whether noise cancellation occurred at the block 304. At block 308, the amplified data set undergoes analog to digital (A/D) conversion and is stored in the recorder 212. A digitized data set can comprise millions of rows of data.

After the acquired data set is stored, at a block 310 a check is performed to see whether at least four data runs for the sample have occurred (e.g., have acquired at least four data sets). If four data sets for a given sample have been obtained, then lowpass filtering occurs at a block 312. Otherwise, the next data run is initiated (return to the block 300).

After lowpass filtering (block 312) and bandpass filtering (at a block 314) the digitized data sets, the data sets are converted to the frequency domain at a Fourier transform block 316.

Next, at a block 318, like data sets are correlated with each other at each data point. For example, the first data set corresponding to the first data run (e.g., a baseline or ambient noise data run) and the fourth data set corresponding to the fourth data run (e.g., another noise data run) are correlated to each other. If the amplitude value of the first data set at a given frequency is the same as the amplitude value of the fourth data set at that given frequency, then the correlation value or number for that given frequency would be 1.0. Alternatively, the range of correlation values may be set at between 0-100. Such correlation or comparison also occurs for the second and third data runs (e.g., the sample data runs). Because the acquired data sets are stored, they can be accessed at a later time as the remaining data runs are completed.

When the SQUID 206 provides no noise cancellation, then predetermined threshold levels are applied to each correlated data set to eliminate statistically irrelevant correlation values. A variety of threshold values may be used, depending on the length of the data runs (the longer the data runs, greater the accuracy of the acquired data) and the likely similarity of the sample's actual emission spectrum to other types of samples. In addition to the threshold levels, the correlations are averaged. Use of thresholds and averaging correlation results in the injected noise component becoming very small in the resulting correlated data set.

If noise cancellation is provided at the SQUID 206, then the use of thresholds and averaging correlations are not necessary.

Once the two sample data sets have been refined to a correlated sample data set and the two noise data sets have been refined to a correlated noise data set, the correlated noise data set is subtracted from the correlated sample data set. The resulting data set is the final data set (e.g., a data set representative of the emission spectrum of the sample) (block 320).

Since there can be 8600 data points per Hz and the final data set can have data points for a frequency range of DC-50 kHz, the final data set can comprise several hundred million rows of data. Each row of data can include the frequency, amplitude, phase, and a correlation value.

### III. METHODS OF PRODUCING AN OPTIMIZED TIME-DOMAIN SIGNAL

It has been discovered that sample-dependent spectral features in a low-frequency time-domain signal obtained for a given sample can be optimized by recording time-domain signals for the sample over a range of noise levels. The range can provide power gain on the noise injected into the sample during signal recording. The recorded signals are then processed to reveal spectral signal features. The time domain signal having an optimal spectral-features score, as detailed below, is selected. The selection of optimized or near-optimized time-domain signals is useful because it has been found, also in accordance with the invention, that transducing a chemical or biological system with an optimized time-domain signal gives a stronger and more predictable response than with a non-optimized time-domain signal. In other words, selecting an optimized (or near-optimized) time-domain signal is useful in achieving reliable, detectable sample effects when a target system is transduced by the sample signal.

In general, the range of injected noise levels over which time-domain signals are typically recorded between about 0 to 1 volt, typically, or alternatively, the noise injected is preferably between about 30 to 35 decibels above the molecular electromagnetic emissions sought to be detected, e.g., in the range 70-80-dbm. The number of samples that are recorded, i.e., the number of noise-level intervals over which time-domain signals are recorded may vary from 10-100 or more. This variance is typical and occurs over sufficiently small intervals such that a good optimum signal can be identified. For example, the power gain of the noise generator level can be varied over 50 20 mV intervals. As will be seen below, when the spectral-feature scores for the signals are plotted against level of injected noise, the plot shows a peak extending over several different noise levels when the noise-level increments are suitable small.

Embodiment of the present invention contemplate three different methods for calculating spectral-feature scores for the recorded time-domain signals. These method include (1) a histogram bin method, (2) generating an FFT of autocorrelated signals, and (3) averaging of FFTs, and each of these is detailed below.

Although not specifically described, it will be appreciated that each method may be carried out in a manual mode, where the user evaluates the spectra on which a spectral-feature score is based, makes the noise-level adjustment for the next recording, and determines when a peak score is reached, or it may be carried out in an automated or semi-automated mode, in which the continuous incrementing of noise level and/or the evaluation of spectral-feature score, is performed by a computer-driven program.

A. Histogram Method of Generating Spectral Information

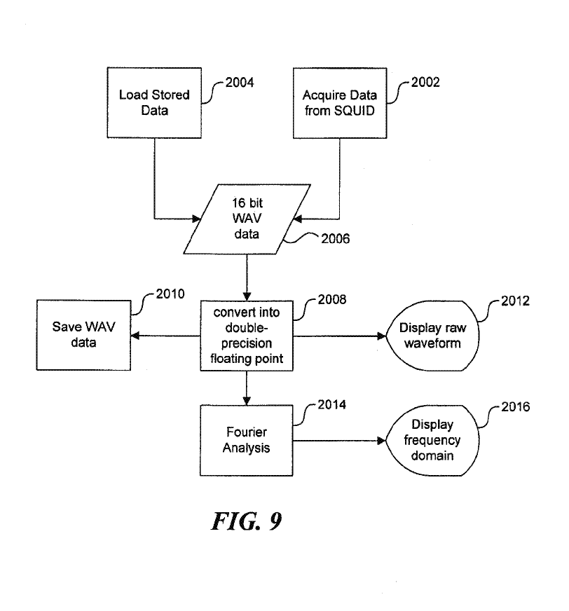

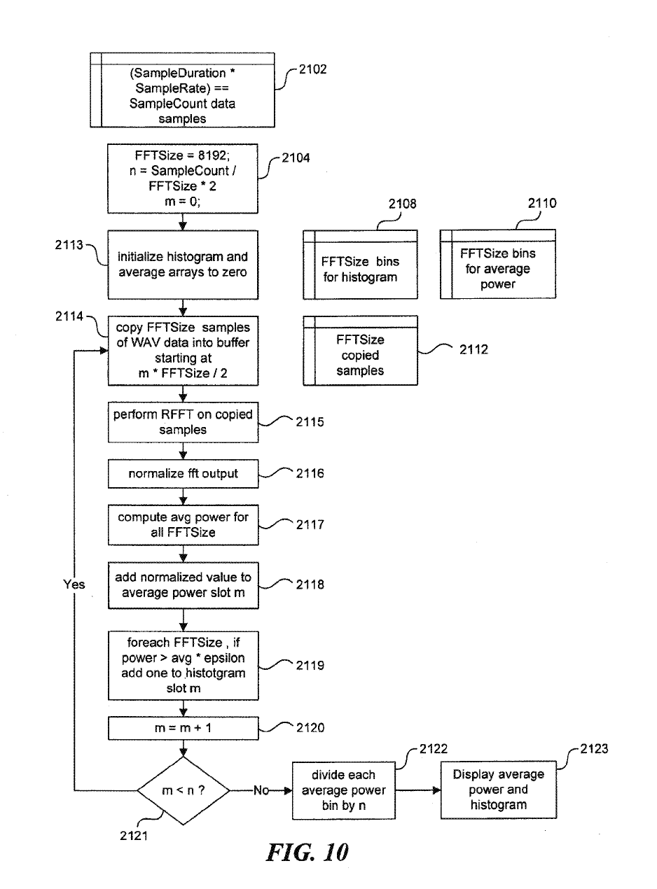

FIG. 9 is a high level data flow diagram in the histogram method for generating spectral information. Data acquired from the SQUID (box 2002) or stored data (box 2004) is saved as 16 bit WAV data (box 2006), and converted into double-precision floating point data (box 2008). The converted data may be saved (box 2010) or displayed as a raw waveform (box 2012). The converted data is then passed to the algorithm described below with respect to FIG. 10, and indicated by the box 2014 labeled Fourier Analysis. The histogram can be displayed at 2016. Alternatively, and as will be described below, the converted data may be passed to one of two additional al

With reference to FIG. 10, the general flow of the histogram algorithm is to take a discrete sampled time-domain signal and use Fourier analysis to convert it to a frequency domain spectrum for further analysis. The time-domain signals are acquired from an ADC (analog/digital converter) and stored in the buffer indicated at 2102. This sample is SampleDuration seconds long, and is sampled at SampleRate samples per second, thus providing SampleCount (SampleDuration*SampleRate) samples. The FrequencyRange that can be recovered from the signal is defined as half the SampleRate, as defined by Nyquist. Thus, if a time-series signal is sampled at 10,000 samples per second, the FrequencyRange will be 0 Hz to 5 kHz. One Fourier algorithm that may be used is a Radix 2 Real Fast Fourier Transform (RFFT), which has a selectable frequency domain resolution (FFTSize) of powers of two up to 2¹⁶. An FFTSize of 8192 is selected, to provide provides enough resolution to have at least one spectrum bin per Hertz as long as the FrequencyRange stays at or below 8 kHz. The SampleDuration should be long enough such that SampleCount >(2*) FFTSize*10 to ensure reliable results.

Since this FFT can only act on FFTSize samples at a time, the program must perform the FFT on the samples sequentially and average the results together to get the final spectrum. If one chooses to skip FFTSize samples for each FFT, a statistical error of 1/FFTSizê0.5 is introduced. If, however, one chooses to overlap the FFT input by half the FFTSize, this error is reduced to 1/(0.81*2*FFTSize)̂0.5. This reduces the error from 0.0110485435 to 0.0086805556. Additional information about errors and correlation analyses in general, consult Bendat & Piersol, “Engineering Applications of Correlation and Spectral Analysis”, 1993.

Prior to performing the FFT on a given window, a data tapering filter may be applied to avoid spectral leakage due to sampling aliasing. This filter can be chosen from among Rectangular (no filter), Hamming, Hanning, Bartlett, Blackman and Blackman/Harris, as examples.

In an exemplary method, and as shown in box 2104, we have chosen 8192 for the variable FFTSize, which will be the number of time-domain samples we operate on at a time, as well as the number of discrete frequencies output by the FFT. Note that FFTSize=8192 is the resolution, or number of bins in the range which is dictated by the sampling rate. The variable n, which dictates how many discrete RFFT's (Real FFT's) performed, is set by dividing the SampleCount by FFTSize*2, the number of FFT bins. In order for the algorithm to generate sensible results, this number n should be at least 10 to 20 (although other valves are possible), where more may be preferred to pick up weaker signals. This implies that for a given SampleRate and FFTSize, the SampleDuration must be long enough. A counter m, which counts from 0 to n, is initialized to zero, also as shown in box 2104.

The program first establishes three buffers: buffer 2108 for FFTSize histogram bins, that will accumulate counts at each bin frequency; buffer 2110 for average power at each bin frequency, and a buffer 2112 containing the FFTSize copied samples for each m.

The program initializes the histograms and arrays (box 2113) and copies FFTSize samples of the wave data into buffer 2112, at 2114, and performs an RFFT on the wave data (box 2115). The FFT is normalized so that the highest amplitude is 1 (box 2116) and the average power for all FFTSize bins is determined from the normalized signal (box 2117). For each bin frequency, the normalized value from the FFT at that frequency is added to each bin in buffer 2108 (box 2118).

In box 2119 the program then looks at the power at each bin frequency, relative to the average power calculated from above. If the power is within a certain factor epsilon (between 0 and 1) of the average power, then it is counted and the corresponding bin is incremented in the histogram buffer at 16. Otherwise it is discarded.

Note that the average power it is comparing to is for this FFT instance only. An enhanced, albeit slower algorithm might take two passes through the data and compute the average over all time before setting histogram levels. The comparison to epsilon helps to represent a power value that is significant enough for a frequency bin. Or in broader terms, the equation employing epsilon helps answer the question, “is there a signal at this frequency at this time?” If the answer is yes, it could due be one of two things: (1) stationary noise which is landing in this bin just this one time, or (2) a real low level periodic signal which will occur nearly every time. Thus, the histogram counts will weed out the noise hits, and enhance the low level signal hits. So, the averaging and epsilon factor allow one to select the smallest power level considered significant.

Counter m is incremented at box 2120, and the above process is repeated for each n set of WAV data until m is equal to n (box 2121). At each cycle, the average power for each bin is added to the associated bin at 2118, and each histogram bin is incremented by one when the power amplitude condition at 2114 is met.

When all n cycles of data have been considered, the average power in each bin is determined by dividing the total accumulated average power in each bin by n, the total number of cycles (box 2122) and the results displayed (box 2123). Except where structured noise exists, e.g., DC=0 or at multiples of 60 Hz, the average power in each bin will be some relatively low number.

The relevant settings in this method are noise gain and the value of epsilon. This value determines a power value that will be used to distinguish an event over average value. At a value of 1, no events will be detected, since power will never be greater than average power. As epsilon approaches zero, virtually every value will be placed in a bin. Between 0 and 1, and typically at a value that gives a number of bin counts between about 20-50% of total bin counts for structured noise, epsilon will have a maximum “spectral character,” meaning the stochastic resonance events will be most highly favored over pure noise.

Therefore, one can systematically increase the power gain on the noise input, e.g., in 50 mV increments between 0 and 1 V, and at each power setting, adjust epsilon until a histogram having well defined peaks is observed. Where, for example, the sample being processed represents a 20 second time interval, total processing time for each different power and epsilon will be about 25 seconds. When a well-defined signal is observed, either the power setting or epsilon or both can be refined until an optimal histogram, meaning one with the largest number of identifiable peaks, is produced.

Under this algorithm, numerous bins may be filled and associated histogram rendered for low frequencies due to the general occurrence of noise (such as environmental noise) at the low frequencies. Thus, the system may simply ignore bins below a given frequency (e.g., below 1 kHz), but still render sufficient bin values at higher frequencies to determine unique signal signatures between samples.

Alternatively, since a purpose of the epsilon variable is to accommodate different average power levels determined in each cycle, the program could itself automatically adjust epsilon using a predefined function relating average power level to an optimal value of epsilon.

Similarly, the program could compare peak heights at each power setting, and automatically adjust the noise power setting until optimal peak heights or character is observed in the histograms.

Although the value of epsilon may be a fixed value for all frequencies, it is also contemplated to employ a frequency-dependent value for epsilon, to adjust for the higher value average energies that may be observed at low frequencies, e.g., DC to 1,000. A frequency-dependent epsilon factor could be determined, for example, by averaging a large number of low-frequency FFT regions, and determining a value of epsilon that “adjusts” average values to values comparable to those observed at higher frequencies.

B. FFT of Autocorrelated Signals

In a second general method for determining spectral-feature scores, time-domain signals recorded at a selected noise are autocorrelated, and a fast Fourier transform (FFT) of the autocorrelated signal is used to generate a spectral-features plot, that is, a plot of the signal in the frequency domain. The FFTs are then used to score the number of spectral signals above an average noise level over a selected frequency range, e.g., DC to 1 kHz or DC to 8 kHz.

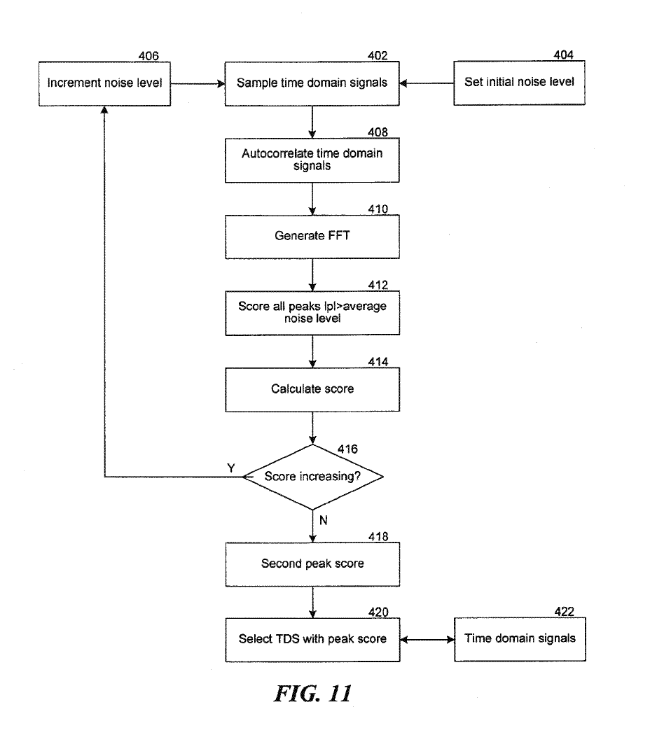

FIG. 11 is a flow diagram of steps carried out in scoring recorded time-domain signals according to this second embodiment. Time-domain signals are sampled, digitized, and filtered as above (box 402), with the gain on the noise level set to an initial level, as at 404. A typical time domain signal for a sample compound 402 is autocorrelated, at 408, using a standard autocorrelation algorithm, and the FFT of the autocorrelated function is generated, at 410, using a standard FFT algorithm.

An FFT plot is scored, at 412, by counting the number of spectral peaks that are statistically greater than the average noise observed in the autocorrelated FFT and the score is calculated at 414. This process is repeated, through steps 416 and 406, until a peak score is recorded, that is, until the score for a given signal begins to decline with increasing noise gain. The peak score is recorded, at 418, and the program or user selects, from the file of time-domain signals at 422, the signal corresponding to the peak score (box 420).

As above, this embodiment may be carried out in a manual mode, where the user manually adjusts the noise setting in increments, analyzes (counts peaks) from the FFT spectral plots by hand, and uses the peak score to identify one or more optimal time-domain signals. Alternatively, one or more aspects of the steps can be automated.

C. Averaged FFTs

In another embodiment for determining spectral-peak scores, an FFT of many, e.g., 10-20 time domain signals at each noise gain are averaged to produce a spectral-peaks plot, and scores are calculated as above.

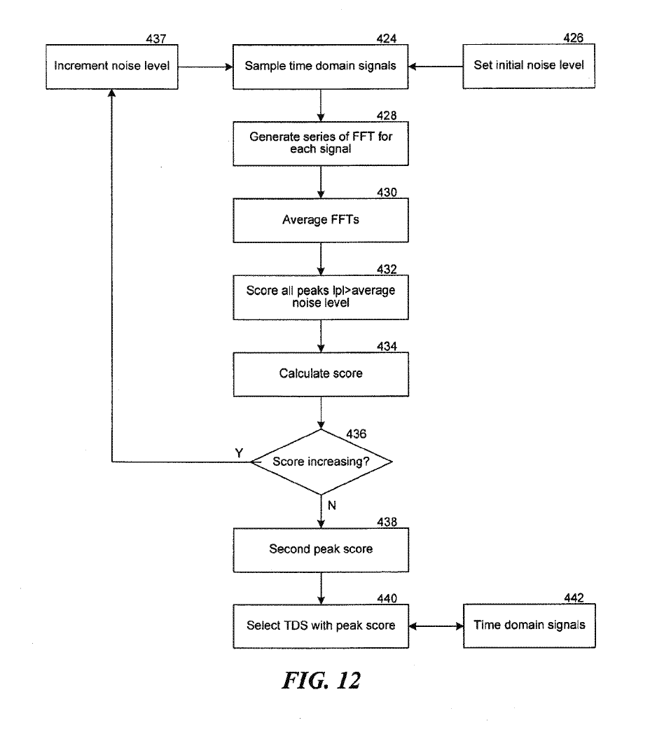

FIG. 12 is a flow diagram of steps carried out in scoring recorded time-domain signals according to this third embodiment. Time-domain signals are sampled, digitized, and filtered as above (box 424), with the gain on the noise level set to an initial level, as at 426. The program then generates a series of FFTs for the time domain signal(s) at each noise gain, at 428, and these plots are averaged at 430. Using the averaged FFT plot, scoring is done by counting the number of spectral peaks that are statistically greater than the average noise observed in the averaged FFT, as at 432, 434. This process is repeated, through the logic of 436 and 437, until a peak score is recorded, that is, until the score for a given signal begins to decline with increasing noise gain. The peak score is recorded, at 438, and the program or user selects, from the file of time-domain signals at 442, the signal corresponding to the peak score (box 440).

As above, this method may be carried out in a manual, semi-automated, or fully automated mode.

### IV. FORMING TRANSDUCING SIGNALS

Signals for various therapeutic uses, or for uses to otherwise affect biological systems, may be generated directly from processed time-domain signals. Signals may also be formed by constructing a signal having specific identified peak frequencies. For example, the system can take advantage of “signal-activity relationship” in which molecular signal features, e.g., characteristic peak frequencies of a compound, are related to actual chemical activity for the compound, analogous to structure-activity relationships used in traditional drug design. In one general application, signal-activity relationships are used for drug screening, following, in one example, the following method.

First, one or more compounds having desired activity are identified, e.g., compounds capable of producing a desired response in a biological system. The system records a time-series signal for one of these compounds, and the wave form is processed or otherwise optimized to identify low-frequency peaks for that compound. (“Low-frequency” in this case refers to peaks at or below 10 kHz.) The steps are repeated for each of a group of structurally related compounds. The structurally related compounds include those that are active (produce a desired response), and some that are inactive for the tested biological response. The spectral components of the two groups of compounds are compared to identify those spectral components that are uniquely associated with compound activity. For example, by analyzing forms from three active and two inactive compounds, one may identify those peaks in the signal found in the active compounds, and not in the inactive compounds, some of which are presumed to provide the desired biological response.

In like manner, the system may record and optimize any unknown compound. One may then analyze the resulting wave form with signals associated with known compounds to see if the unknown compound displays structural features associated the desired activity, and lack components associated with inactive components to help identify an active compound. Rules derivable from signal-structure relationships are more accessible and more predictive than rules derived from structure-activity relationships, since activity can be correlated with a relatively small number of peak frequencies, rather than a large number of structural variables. Thus, for use in drug design, one can use the presence or absence of certain peak frequencies to guide synthesis of drugs with improved pharmacokinetic or target activity. For example, if poor pharmacokinetic properties, or an undesired side effect, can be correlated with certain peak frequencies, novel compounds that lack or have reduced amplitudes in these frequencies would be suggested. As a result, the inventive system greatly simplifies the task of formulating useful drug-design rules, since the rules can be based on the relatively small number of peak frequencies.

A large database of spectral peak frequencies representing numerous compounds would allow one to combine signal features to “synthesize” virtually any drug or drug-combination property desired. By combining this database with a chemical compound database, one may generate chemical structures that display a desired peak-frequency set. This approach would be similar to current computer-assisted chemical-synthesis programs used to generate compound syntheses for novel compounds of interest.

The system can employ numerous signal processing techniques, as described herein. For example, signals from two or more structurally-related compounds can be compared with one or more signals from a structurally-related, but inactive or undesirable compound to identify only the desired frequency components between the signals. A resulting signal may thus be constructed that includes only the desired peaks. By then generating a time-domain signal, that time-domain signal may be used for therapeutic purposes.

Of course, a time-domain signal may be generated from the processed frequency-domain signal of a single compound. For example, one may obtain the frequency-domain signal for a desired sample, and produce a processed, desired signal. From the processed signal, a time-domain signal may be generated using known techniques, which can then be employed for therapeutic or other uses as an analog to the compound itself.

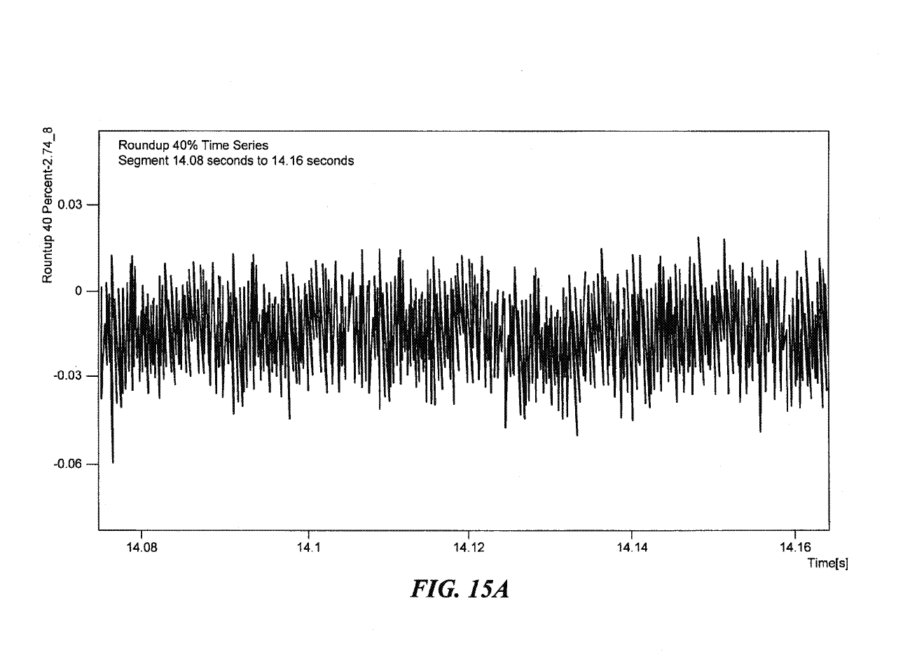

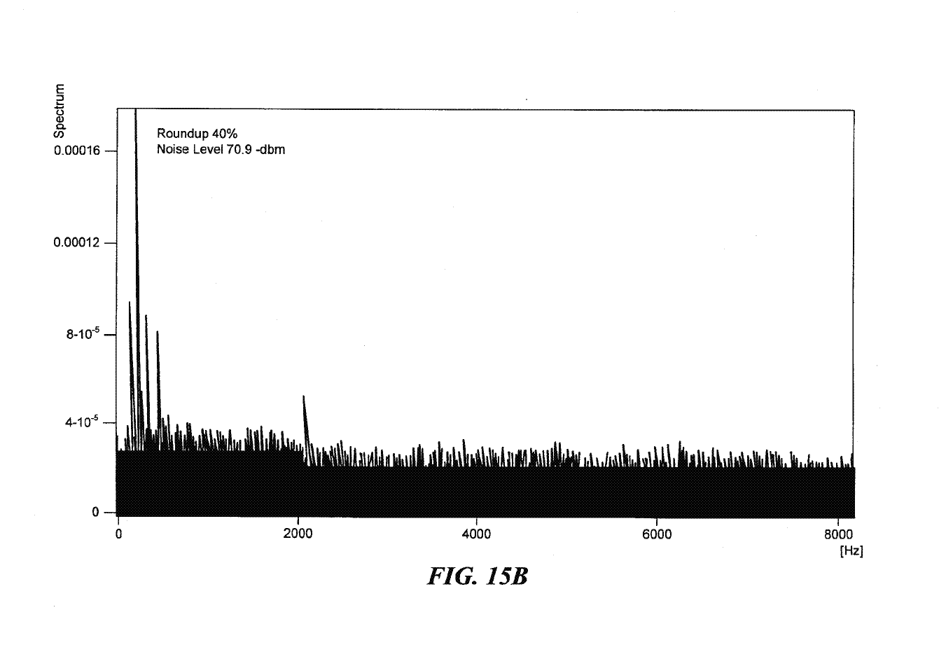

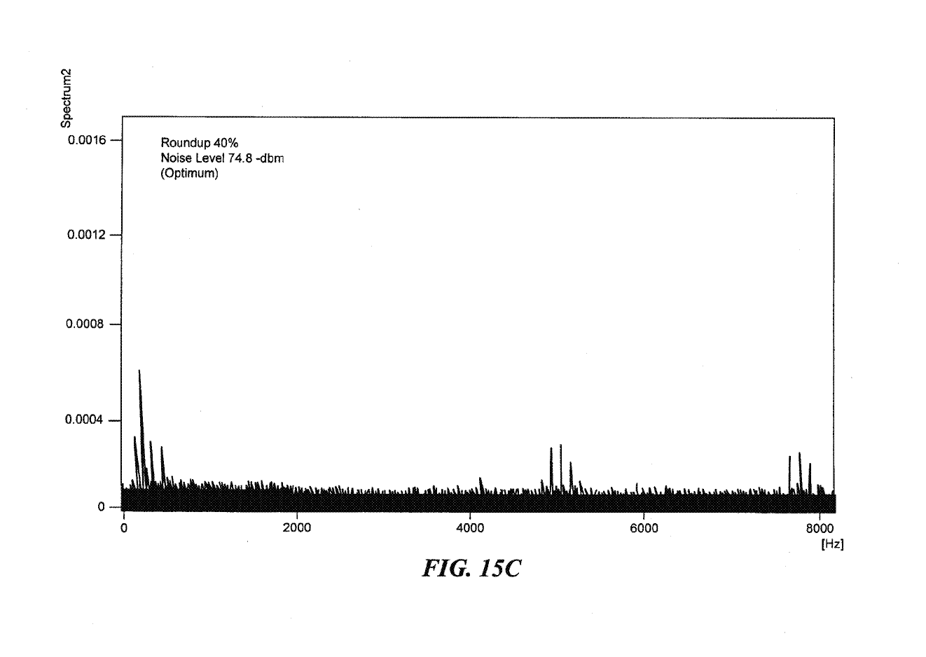

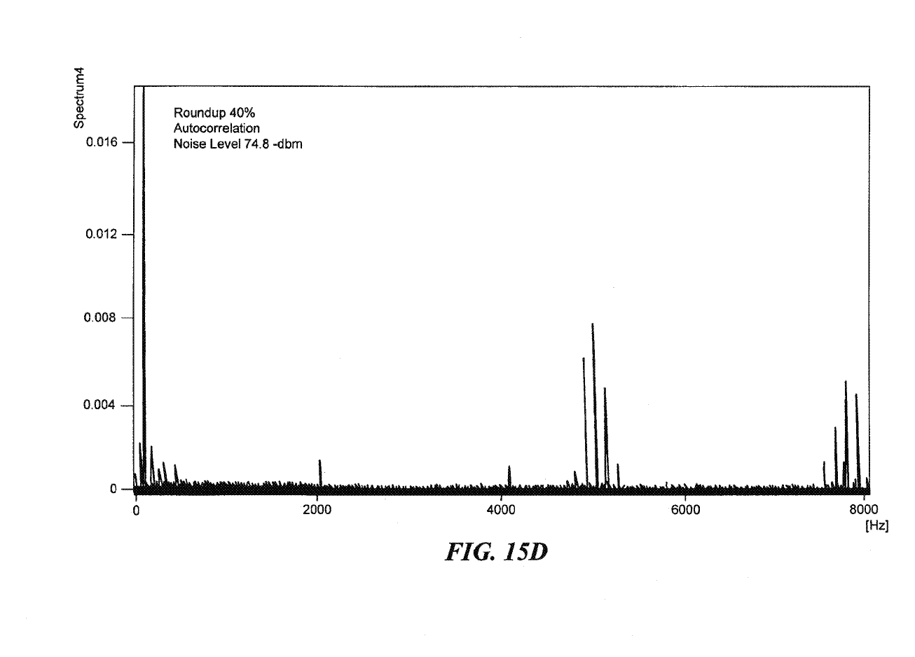

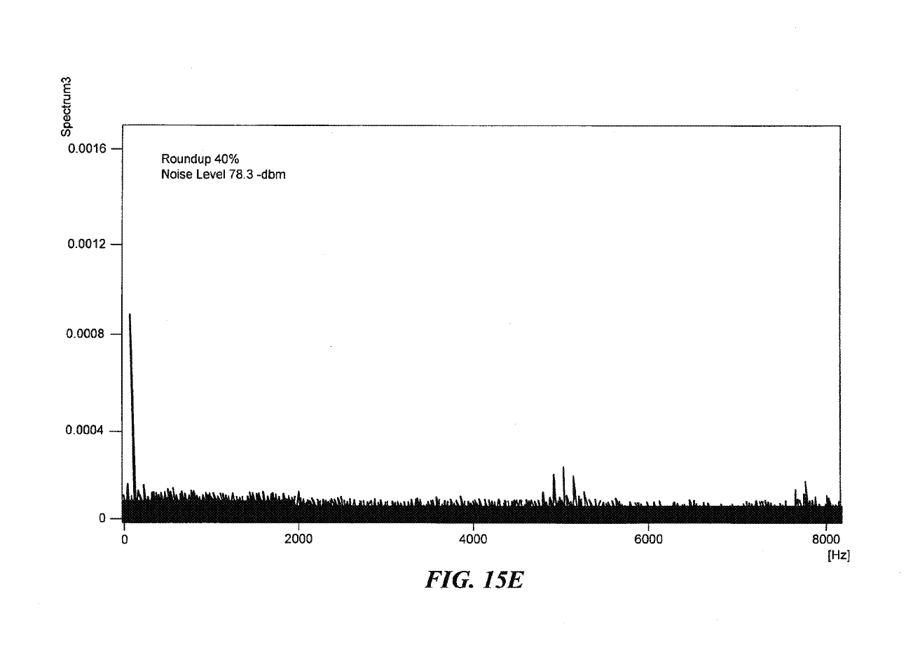

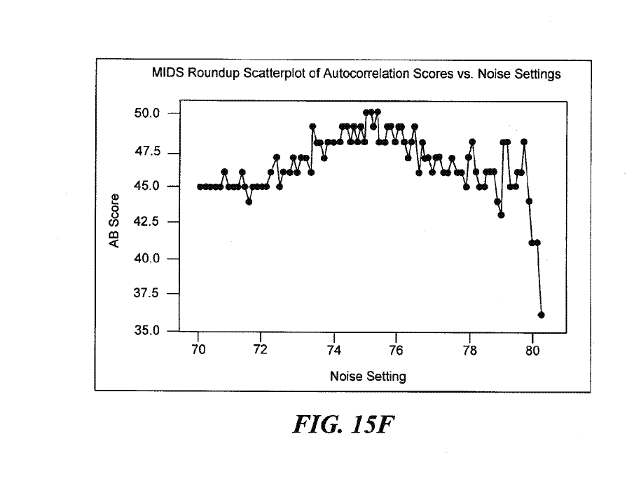

FIG. 15A shows a typical time domain signal for a sample compound. In this embodiment, the herbicide glyphosphate (RoundupR). The segment shown here is taken over the time interval 14.08 to 14.16 seconds. The time-domain signal is then autocorrelated using a standard autocorrelation algorithm, and the FFT of the autocorrelated function is generated using a standard FFT algorithm.

Using the FFT plot, such as illustrated in FIGS. 15B-15E, the plot is scored by counting the number of spectral peaks that are statistically greater than the average noise observed in the autocorrelated FFT. This process is repeated until a peak score is recorded, that is, until the score for a given signal begins to decline with increasing noise gain. The peak score is recorded and the program or user selects, from the file of time-domain signals, the signal corresponding to the peak score.

The series of autocorrelated FFT plots in FIGS. 15B-15E illustrate the signal analysis involved in this method. At a noise level of 70.9-dbm (FIG. 15B), very few peaks above background noise are observed (the highest spike represents 60 cycle noise). At the optimum noise level of 74.8-dbm (FIGS. 15C and 15D), which represent different recordings at the same noise level), numerous peaks statistically greater than average noise are observed throughout the frequency range of DC-8 kHz. Several of these peaks are less prominent or have disappeared at the higher noise gain of 78.3-dbm (FIG. 15E).

When the spectral-features scores for these signals are plotted as a function of noise setting, as shown in FIG. 15F, the peak score in the noise setting of about 75-dbm is observed. From this plot, the time-domain signals corresponding to one or the peak score is selected.

### V. TRANSDUCTION APPARATUS AND PROTOCOLS

This section describes equipment and methodology for transducing a sample with signals formed in accordance with aspects of the present invention, and summarizes experiments that demonstrate the response of various biological systems to time-domain signals of the present invention. The signals employed in these experiments, which are optimized time-domain signals formed in accordance with the method described above demonstrate the ability of signals in accordance with the invention to produce a compound-specific response in various biological systems.

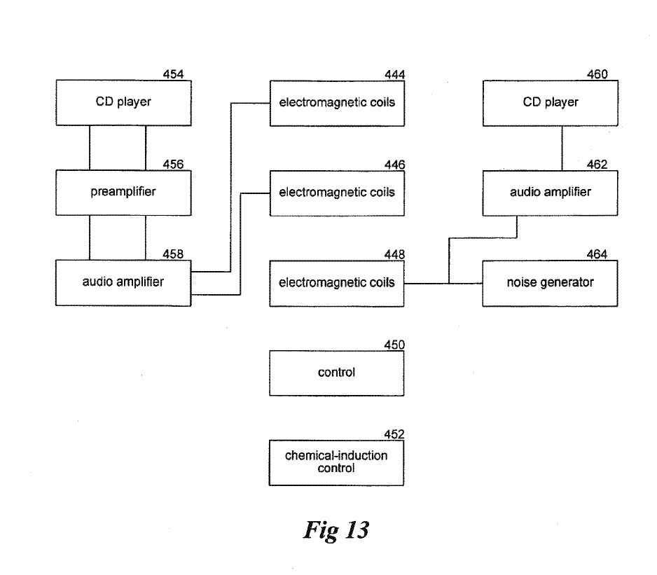

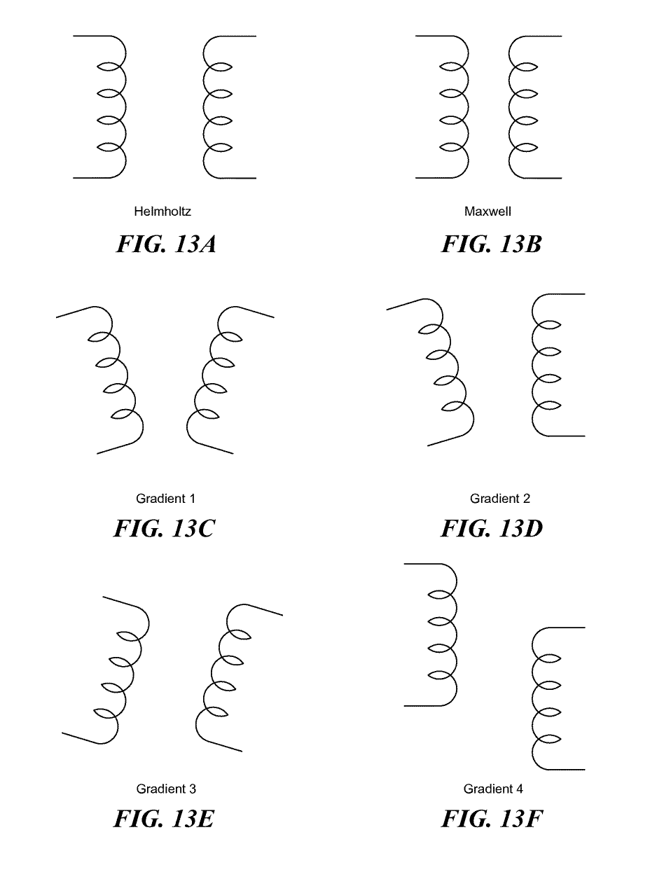

FIG. 13 shows the layout of equipment for transducing a sample with an agent-specific signal, in accordance with the invention. The particular layout accommodates five different samples, including three samples 444, 446, and 448 which are held within transductions coils, and exposed to electromagnetic signals, a sample 450 that serves as a control, and a sample 452 that serves as a chemical-induction control. The system of FIG. 13 may be used for experimentation; if used for treating a patient, then some elements may be omitted, such as 448, 450, 452, etc.

Transduction by an agent-specific signal is carried out by “playing” the optimized agent-specific signal to the sample, using, where the signal is recorded on a CD, and is played on a CD recorded 454 through a preamplifier 456 and an audio amplifier 458. This signal is supplied to the electromagnetic coils 444 and 446 through separate channels, as shown. In one embodiment, a Sony Model CDP CE375 CD Player is used. Channel 1 of the Player is connected to CD input 1 of Adcom Pre Amplifier Model GFP 750. Channel 2 is connected to CD input 2 of Adcom Pre Amplifier Model GFP 750. CD's are recorded to play identical signals from each channel. Alternatively, CD's may be recorded to play different signals from each channel. The coil in sample 448 is used primarily to produce a white noise field as a control for experiments. For example, a GR analog noise generator provides a white Gaussian noise source for this coil. Alternatively, this coil can be used to play any prerecorded transduction signal via a second Crown amplifier.

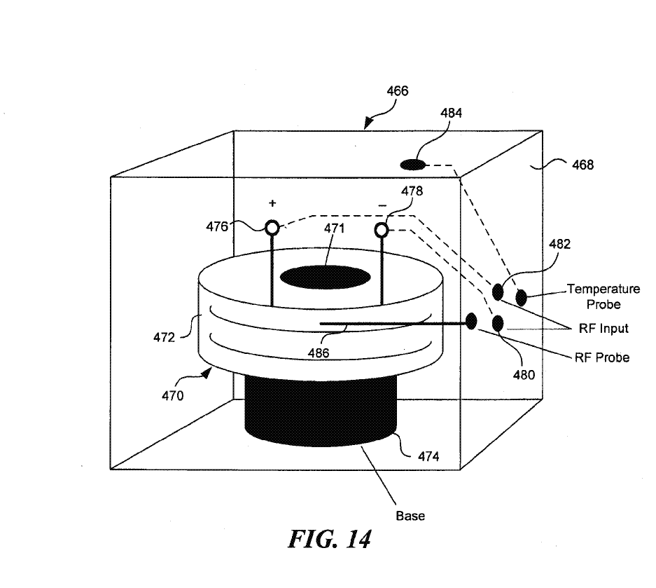

FIG. 14 shows sample transduction equipment 466 such as represented by any of samples 444, 446, and 448 in FIG. 13. The equipment includes a chamber 468 housing an electromagnet 470, and various probes for monitoring conditions within the chamber, e.g., temperature. The electromagnet sits on a base 474, and includes, conventionally a toroid ferromagnetic core and wire windings.

In one embodiment, the coils are engineered and manufactured by American Magnetics to provide uniform performance between coils. Each coil consists of 416 turns of No. 8 gauge (awg) square copper magnet wire, enamel coated, about a 2″ air core. Each coil can produce approximately 1500 Gauss in the center at 10 Volts RMS at 10 Amps RMS at 11 Hertz without exceeding a 15 degree Celsius rise in temperature.

In operation, the sample, e.g., a human patient or a portion of the patient's body is place between the centrally between the coils. Thus, for example, the coils may be at opposite ends of a support bed, or on opposite sides of the bed, and on opposite sides of the patient's head. The coil is then activated, using signal generation equipment like that shown in FIG. 13, for a predetermined therapeutic period, e.g., 1 to several hours.

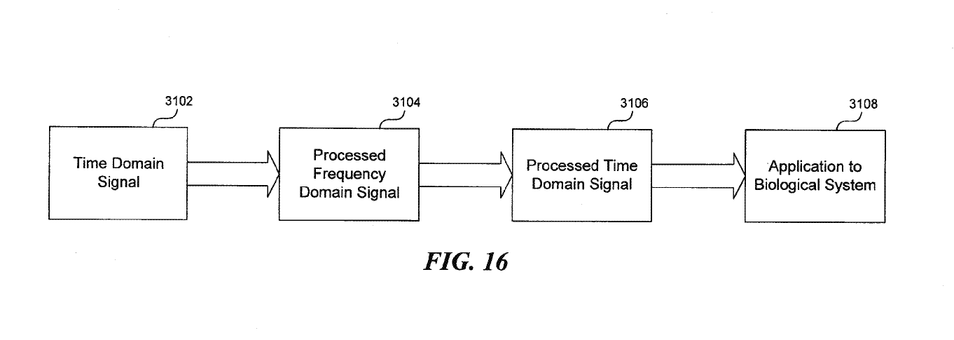

FIG. 16 shows an example of a process for creating and applying signals under the inventive system. Under block 3102, the system receives and records a time domain signal from one or more samples, in a manner described above. Under block 3104, the system generates a frequency domain signal, and then processes that signal to isolate the desired frequency components from undesired components. Under block 3106, the processed frequency domain signal is converted back into a time domain signal. The time domain signal may then be applied to a biological system to generate a desired result, under block 3108.

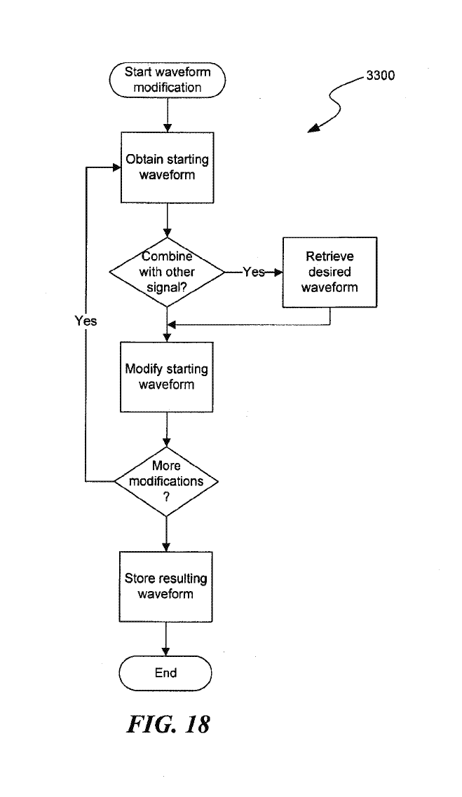

Referring to FIG. 18, a method 3300 for modifying waveforms begins in block 3302 where the user obtains a starting waveform. For example, the user, using standard user interface techniques, selects and retrieves from data storage a desired waveform. Alternatively, the user may obtain a signal during “live” interrogation of a sample.

In block 3304, the user can combine the starting waveform with another waveform and if so desired, the user retrieves another waveform under block 3306. Of course, the user can simply modify the starting waveform, if desired.

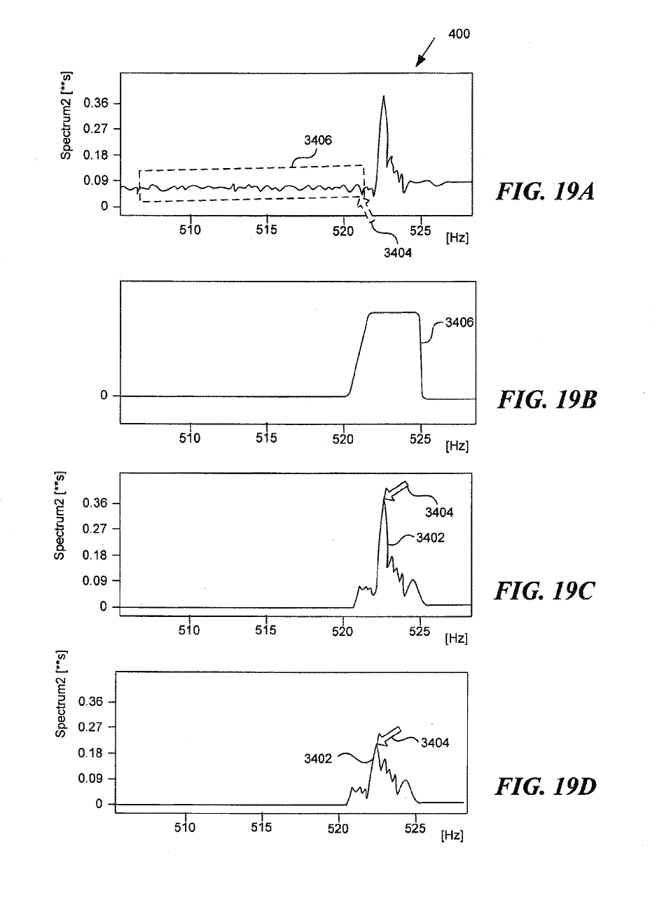

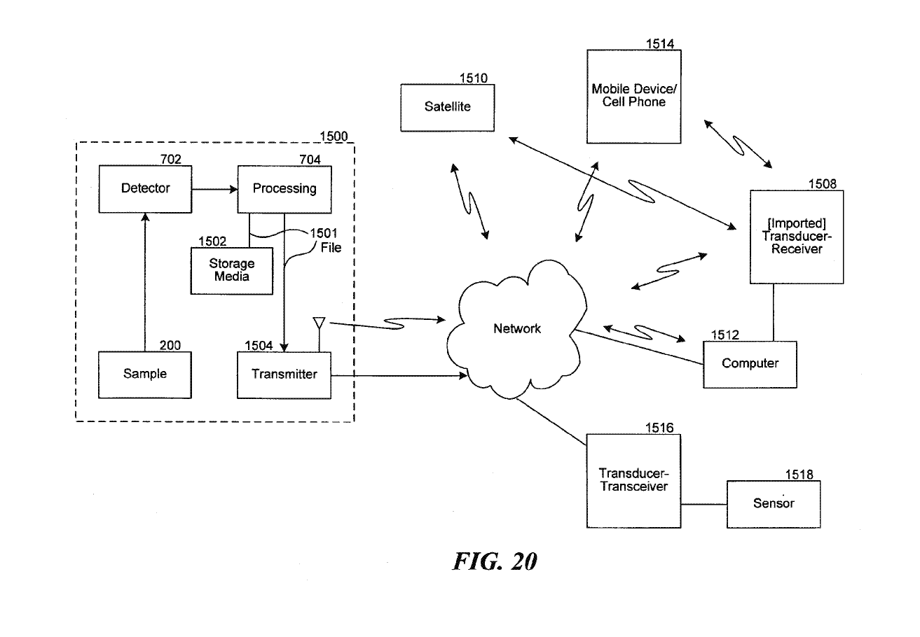

Under block 3308, the user modifies the starting waveform using any of a variety of techniques. FIG. 19C shows an example where the user may simply employ standard user interface techniques, such as a mouse, to manipulate a pointer 3404 and attenuate (or amplify) one or more frequency peaks in the starting waveform as displayed on a display device. For example, the user can simply click on a peak 3402 of a displayed portion of a waveform and, using the mouse, drag the peak down to attenuate its magnitude, as shown in FIG. 19D.

Many other techniques may be employed. The user may simply select a portion of a waveform, cut or copy it, and then paste it into the starting waveform. For example, referring to FIG. 19A, the user may move the cursor about a portion of a waveform to select that portion of the waveform (shown as a dashed line box 3406). Once selected, the user can select from one of several menu choices, such as to cut that portion from the waveform. Alternatively, once selected, the user may modify that portion of the waveform, such as by replacing it with a flat line, attenuate it, amplify it, or perform various other signal processing techniques.

The system may employ a library of waveforms that can be inserted or employed as desired by the user. The user can select a portion of the signal and cause it to filter out all peaks, thereby eliminating noise or undesired frequency components in the waveform. For example, FIG. 19B shows an example of a waveform or filter signal 3408 that may be stored in a library. By applying the signal 3408 to the waveform of FIG. 19A, the system provides the resulting, processed waveform shown in FIG. 19C.

The system may employ various mathematical techniques under block 3308 to modify the starting waveform. For example, the starting waveform may be combined using a variety of mathematical techniques with one or more waveforms retrieved under block 3306. Examples of such mathematical operations include: addition, subtraction, multiplication, convolution, cross-correlation, scaling of starting waveform (SW) as a linear or non-linear function of other waveforms, etc.

Under block 3310, the routine 3300 queries the user regarding whether more modifications to the starting waveform are desired. If so, the routine loops back to again perform under blocks 3304 through 3308. If not, then in block 3312, the user may store the resulting waveform. The stored waveform can then be used for future modifications to other starting waveforms, used for therapeutic effect, or a variety of other reasons, described herein.

The following are some examples of additional techniques to shape a waveform or set of waveforms in time series.

Passive Filters: simple electronic filters are based on combinations of resistors, inductors and capacitors (or logical or programmed representations of same). These filters can be used to shape the waveform prior to recording, prior to processing, or prior to transduction. Various existing software packages or routines permit a user to model the responsive electronic filters. Such software routines may be readily employed under the inventive system to filter frequency domain waveforms using software modeled versions of such electronic filters.

Active Filters: hardware or software filters can also be implemented using a combination of passive components and amplifiers to create active filters. These can have high Q, and achieve resonance without the use of inductors. As with passive filters, software applications or routines exist for modeling the response of active filters, and such routines may be employed herein to modify waveforms using one or more active filter models. The inventive system may employ similar existing software routines to implement with the filters, processing and shaping described below.

Digital Filters: a digital filter is an electronic filter (usually linear), in discrete time, that is normally implemented through digital electronic computation. Digital filters are typically either finite impulse response (FIR) or infinite impulse response (IIR), though there are others, such as a hybrid class of filters known as truncated infinite impulse response (TIIR) filters, which show finite impulse responses despite being made from IIR components.

Digital Signal Processing: digital signal processing (e.g., executed as a computer program) may simulate, e.g., comb filter having a tapped delay line. The program selects numbers from a string of digital values representing the signal, at a spacing that simulates a comb of a tapped delay line. These numbers are multiplied by constants, and added together to make the output of the filter. DSP allows for multiple pass bands or multiple band gaps, essentially allowing only a select set of frequencies to make it to an output stage.

Wave Shaping: many well-known methods exist for shaping a waveform by altering its rise time, sustain time, and decay time, or otherwise altering a signal from, or to a sine wave using full wave rectifiers or pulse width modulation (as examples).

All of the equipment described herein may be scaled to produce systems of greater or lesser size or intensity for various applications. For example, if the system to be used to treat the human patient, then a system having a coil for generating electromagnetic waves to be directed at a patient may be constructed. In one example, a bed having embedded therein round or square Helmholtz coils would receive the time-domain signal created from the processed frequency-domain signal. The patient would then receive the resulting electromagnetic wave to induce the desired biological effect that would otherwise be provided by, for example, ingesting the compound from which the signals was generated.

A system for more targeted application of electromagnetic waves to a patient is of course possible. For example, one or more coils may be provided within a small device (such as a helmet, or handheld wand). This output device receives the time-domain signal produced from a desired frequency-domain signal, as noted above. Resulting electromagnetic waves can be directed to specific parts of a patient's body via the output device to produce a desired effect at a localized portion of the patient.

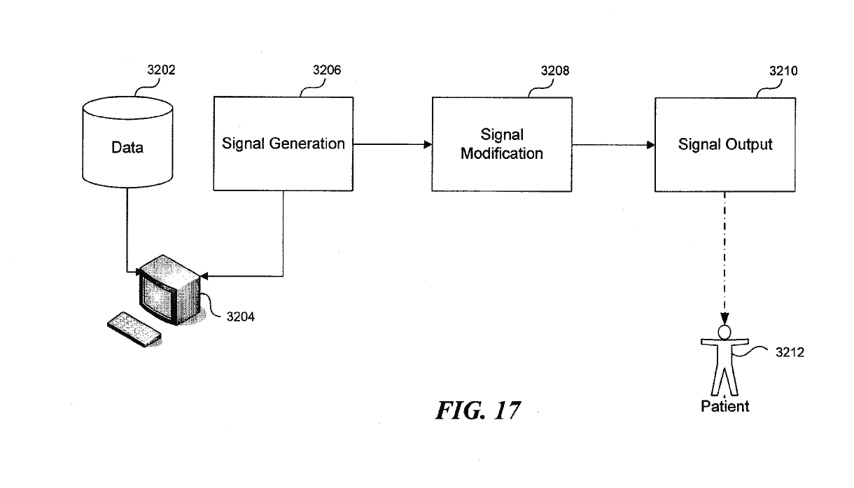

FIG. 17 shows an example of such a signal output device. A database 3202 stores signals from one or more compounds or samples. Alternatively, the signals may be unprocessed frequency- or time-domain signals generated as noted above. A computer 3204 retrieves the signal (or signals) and provides it to a signal generator 3206. For example, the computer retrieves a desired time-domain signal generated from a processed frequency domain signal that was created from a specific compound. The computer then provides the time domain signal to the signal generator 3206 to simply amplify the signal. Alternatively, the computer may retrieve processed frequency-domain signals that the signal generator converts into time-domain signals. The signals output from the signal generator 3206 may be modified by a signal modifier 3208. The signal modifier may perform additional amplification, filtering, and so forth. In an alternative embodiment, the computer 3204 performs the necessary signal generation modification, and thus separate circuitry for the signal generator 3206 and signal modifier 3208 may be omitted. Alternatively, the signal generator 3206 or signal modifier 3208 may be eliminated.

The signal output device 3210 receives the signal and applies to a patient 3212. As noted above, the signal output device may be a patient bed having embedded therein one or more coils to output electromagnetic waves. Alternatively, the signal output device 3210 can be a small, handheld device, a wearable device (such as an article of clothing containing a coil), and so forth.

The detector 702 obtains a signal from the sample 200, and that signal is processed by the processing unit 704 to produce a digital file 1501, such as a .wav file. That file may then be stored on a storage media 1502 and distributed or transported to a remote computer or other device. Any of the storage media noted above may be employed for transporting signals or data files.

Aspects of the invention may be implemented in computer-executable instructions, such as routines executed by a general-purpose computer, e.g., a server computer, wireless device or personal computer. Those skilled in the relevant art will appreciate that the invention can be practiced with other communications, data processing, or computer system configurations, including: Internet appliances, hand-held devices (including personal digital assistants (PDAs)), wearable computers, all manner of cellular or mobile phones, multi-processor systems, microprocessor-based or programmable consumer electronics, set-top boxes, network PCs, mini-computers, mainframe computers, and the like. Indeed, the terms “computer,” “computing device,” and similar terms are generally used interchangeably herein, and refer to any of the above devices and systems, as well as any data processor.

Aspects of the invention can be embodied in a special purpose computer or data processor that is specifically programmed, configured, or constructed to perform one or more of the computer-executable instructions explained in detail herein. Aspects of the invention can also be practiced in distributed computing environments where tasks or modules are performed by remote processing devices, which are linked through a communications network, such as a Local Area Network (LAN), Wide Area Network (WAN), or the Internet. In a distributed computing environment, program modules may be located in both local and remote memory storage devices.

Aspects of the invention, such as data files, may be stored or distributed on computer-readable media, including magnetically or optically readable computer discs, hard-wired or preprogrammed chips (e.g., EEPROM semiconductor chips), nanotechnology memory, biological memory, or other data storage media. Indeed, computer implemented instructions, data structures, screen displays, wave/signal files, and other data under aspects of the invention may be distributed over the Internet or over other networks (including wireless networks), on a propagated signal on a propagation medium (e.g., an electromagnetic wave(s), a sound wave, etc.) over a period of time, or they may be provided on any analog or digital network (packet switched, circuit switched, or other scheme).

Alternatively, a transmitter 1504 within a signal collection, processing and transmission system 1500 transmits the file to a network 1506 (e.g., the Internet), either via an appropriate cable or hard-wire, or wirelessly. The file then may be transmitted to a computer 1512 via wired or wireless communication.

The file may be transmitted via the network to a remote location, such as to a transducer-receiver 1508. For example, a satellite network 1510 could be used to transmit the file to the transducer-receiver 1508.

The transducer-receiver 1508 could be a standard receiver for receiving the file, and include a transducer for transducing the file as an electromagnetic signal to be applied. In one embodiment, an implanted transducer-receiver is implanted into a patient, body or structure. Where the receiver component of the transducer-receiver 1508 is a wireless receiver, then the transducer/receiver may receive the file wirelessly via the network (or satellite). In an alternative embodiment, a cell phone or mobile device 1514 receives the file from the network and relays it to the transducer-receiver via any known wireless protocol, including short range wireless protocols such as Bluetooth, any of the IEEE802.11 protocols, etc.

A transducer-transceiver 1516, similar to the transducer-receiver 1508, has a sensor 1518. Thus, the transducer-transceiver 1516 can not only similarly receive the transmitted file 1501 and transduce or apply it to a biological system, but also obtain data from the sensor 1518 and transmit that data back to the system 1500 (e.g., via the network).

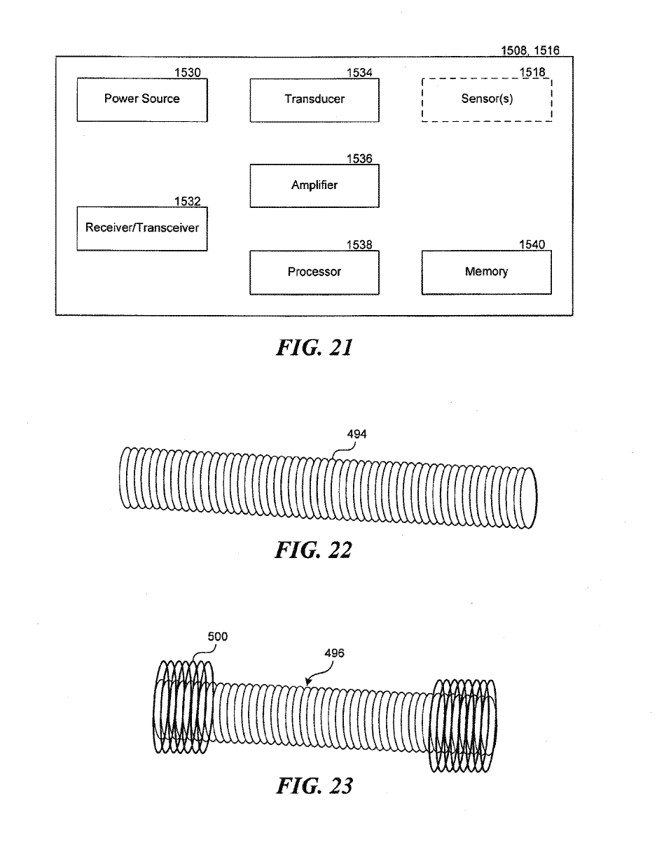

According to FIG. 21, an example of the transducer-receiver 1508 and transducer-transceiver 1516 is provided which includes a power source 1530 for providing power to the device. A receiver-transceiver 1532 wired or wirelessly receives the file 1501, which may then be transduced or applied to a subject or sample via a transducer 1534. The file may be amplified by an amplifier 1536 and/or processed by a processor 1538. Memory 1540 may store the file, or store data obtained from one or more optional sensors 1518.

FIGS. 22 and 23 show transduction coils suitable for use in aspects of the invention. A transducer 494 in FIG. 22 is a long solenoid, e.g., up to several feet in length. The field inside the solenoid is parallel to the axis of the solenoid and constant within the solenoid, going to zero outside the solenoid (in an approximation of an infinitely long solenoid). This finite length coil will have a substantially uniform field only near its center. Thus, by placing the sample or subject at the center of the coil, a substantially uniform magnetic field is created at the sample when the coil is energized with the data file 1501 or MIDS signal.

By adding additional turns to the solenoid, such as additional turns 500 in solenoid 496 in FIG. 23, additional field strength can be added at the ends of the coil to compensate for the fall off of the coil's magnetic fields at its ends.

With either or additional embodiments, the transduction coil may be a small implantable ferromagnetic coil, such as a vascular stent coil capable of receiving transducing signals either by electrodes attached to opposite ends of the coil, by an implantable system (like systems 1508, 1516) or by a remote, inductive system in which an electromagnet is placed near the body surface, against the patient's chest, and signals are transmitted inductively to the implanted coil.

As noted above, the system utilizes, as input, sound files obtained in stochastic resonance experiments and outputs frequencies, amplitudes, and phases of the content sinusoids. The system may employ a software routine, dubbed “peakfinder,” which in turn employ other software packages, such as Octave, and Pd, both of which are open-source and currently supported software platforms.

In addition, two environmental variables may be utilized. A first,: PF_TMP, specifies a temporary directory. A second, PF_BASE, specifies the location of a peakfinder folder. If PF_BASE is not supplied, a peakfinder.sh script attempts to infer it from its own invocation (assuming it is invoked as an absolute pathname). The input file is a stereo soundfile, assumed to be at a standard sample rate of 44100. The file format may be “way,” “au,” or “aiff,” in 16, 24, or 32 bit sample frames. The output file is an ASCII file specifying one sinusoid. For instance:

| | | | | |
|---|---|---|---|---|
| 595 | 100.095749 | 0.095624 | −0.091218 | −0.028693 |
| 1487 | 250.155258 | 0.100177 | 0.040727 | 0.091524 |

Within the chart, the first field is the frequency in units of the fundamental analysis frequency, explained below, the second is the frequency in Hertz, the third is the peak magnitude of the sinusoid, in the input sound file native units, and the fourth and fifth are the amplitudes of the cosine and sine components of the sinusoid, the real and imaginary parts of the complex amplitude. The magnitude could, of course, be inferred from the real and imaginary components. The first field has no physical meaning and is intended for debugging purposes.

A technique for determining the amplitude and frequency of a single sinusoid in white noise is the Maximum Likelihood (ML) method, which has been extended to multiple sinusoids. This methods assume that the number of sinusoids is known in advance. The problem of finding an un-predetermined number of sinusoids is harder to treat mathematically but can be dealt with assuming that the sinusoids in question are adequately separated in frequency. Furthermore, a method is needed to discriminate between the presence and absence of a sinusoid.

The following analysis starts by considering a single sinusoid in white noise and progresses to the problems of multiple sinusoids and non-white (e.g., pink) noise. Given a measured signal:

x[n],n=0, . . . ,N,

the (discrete-time) non-normalized Fourier transform is defined as:

$$FT \{ x [ n ] \} ( k ) = {\sum }_{n = 0}^{N - 1} {e}^{- 2 πi nk / N} x [ n ] ,$$

where k is the frequency in units of the fundamental frequency of the analysis; 2π/N radians per sample. k need not be an integer; in practice extra values of k can be filled in as needed by zero-padding the signal. With the assumption that a single sinusoid is present, its most likely frequency is given by:

k=arg max|FT{x[n]}(k)|.

In other words, the best estimate is simply the value of k at which the Fourier transform's magnitude is the largest.

Next, the system determines if the estimated value of k corresponds to a true sinusoid or simply to random fluctuations. For this, the null hypothesis is analyzed to determine whether x[n] only contains white noise, with mean 0 and RMS amplitude σ, for instance. The Fourier transform at each point k is a sum of N independent random variables, each equal to a sample x[n] times a complex number of unit magnitude, so the mean of each point of the Fourier transform is still zero, and the standard deviation is σ\sqrt{N}. If the tail behavior of the individual noise samples is well behaved (which it is for Gaussian or Uniform noise, for instance) the resulting random variable FT {x[n]}(k) will be very nearly Gaussian for the values of N used (on the order of 10⁶). So the probability of exceeding more than about 5σ\sqrt{N} is very small.

On the other hand, a real-valued sinusoid with peak amplitude a and frequency k (in the usual units of 2π/N) has a Fourier transform magnitude of aN/2. To get a magnitude of 5σ\sqrt{N}, we only need a to be at least

$$a \approx \frac{10 σ}{\sqrt{N}} • \frac{σ}{100}$$

The method zero-pads the recorded sound file (between a factor of two and four, depending on the next power of two), and then reports peaks that exceed this amplitude threshold. A peak is defined as having greater magnitude for the given value of k than for its neighbors, and also having at least half again the magnitude of the twenty neighboring values of k (a band of roughly 20π/N Hz, or ⅓ Hz. for a one-minute sample.)

If several sinusoids are present, provided their frequencies are mutually spaced more than about 20π/N, the above method should resolve them separately; each sinusoid's influence on the calculated Fourier transform drops off as 2/3πk in amplitude at k frequency units away from the peak.

To compensate for the non-white nature of noise signals, the spectral envelope of the measured signal is estimated. The noise can be assumed to be locally white in each narrow range of frequency (20π/N as above), with the value of σ varying gently according to the frequency range chosen. Another issue is to determine whether the injected noise sample can be subtracted from the measured output of the experiment. In such a situation, with an easily measurable transfer function relating the two, even if it is nonlinear, an estimate of the transfer function is used to remove the bulk of the noise from the measured signal. This also increases the sensitivity of the method.

As can be seen from the description provided above, the system allows a user to create waveforms that may be used for therapeutic affect or otherwise induce a reaction in a biological system. Waveforms or spectral series generated from two or more compounds may be obtained. These two signals may then be combined to create a single, combined signal having the properties of the two individual signals. If, for example, the two original signals related to two different compounds having two different therapeutic properties, then the resulting, combined signal would have the combined therapeutic properties of the two compounds. The combined signal may then be manipulated to remove unwanted frequency component that have been found to be associated with side effects or negative reactions in a biological system.

Alternatively, if the two compounds produce similar responses in a biological system, then the two signals generated from those compounds can be compared to identify common frequency components associated with generating the biological effect. A third signal may then be generated that includes only those frequency components associated with the biological effect. Thus, for example, signals from certain pain reliever drugs may be compared to identify common frequency components, and then generate a resulting signal for use in transmission, storage, or application to a biological system. Indeed, the system permits a new signal to be constructed that is not based directly on signals generated from one or more compounds. Instead, the system permits a signal to be generated having only peaks at desired frequencies, where such peaks have a desired result in a biological system. Thus, such a synthesized signal is independent of existing compounds.

### VI. MINIATURIZED MOLECULAR INTERROGATION DATA SYSTEM

A miniaturized MIDS can provide an alternative approach to the SQUID-based biodetection systems discussed in the previous sections. Such a MIDS includes one or more atomic magnetometers that have shown improved sensitivity to measure changes in ultra-low level magnetic fields produced from, e.g., biological samples. Additionally, utilizing the atomic magnetometers, or detectors, allows for a coil-free and room temperature based system, whereas, with the SQUID, cooling is required via liquid helium or nitrogen. The atomic detectors, however, require small magnetic fields in order to operate. Accordingly, application within the shielded apparatus discussed above would provide an environment with little to no external magnetic fields, thus allowing for such operation.

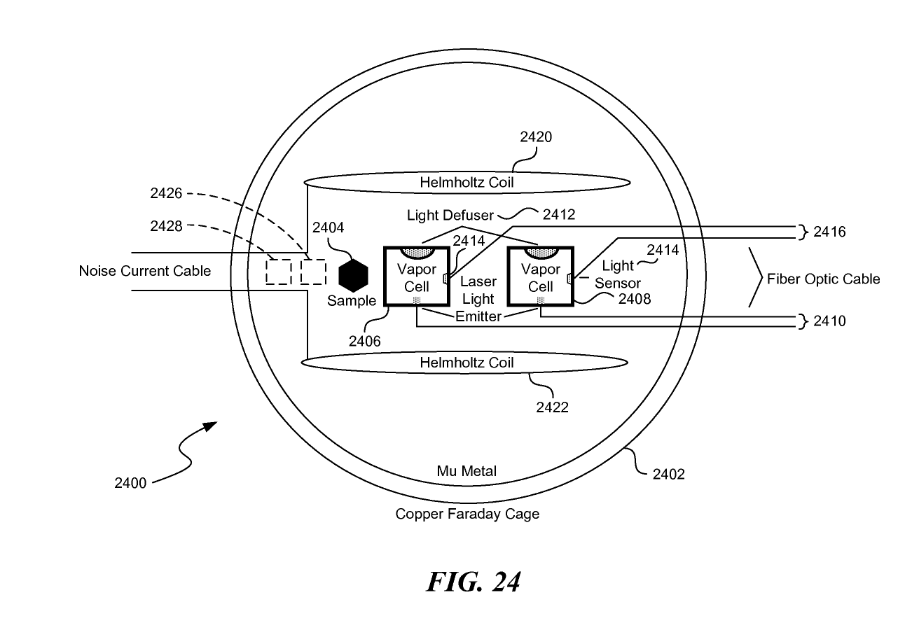

FIG. 24 shows a miniature atomic magnetometer-based MIDS detection apparatus 2400 for use with biological samples. The device 2400 shown can be a top down view of a similar shielding configuration as shown in FIG. 1 above, and the shielding 2402 is similar to room temperature shielding used in the systems described above. This shielding 2402 is utilized in conjunction with attenuation achieved through the use of gradiometers. Fiber optic cabling 2416 and 2410 enters through the shielding via attenuation tubes (e.g., elements 22 and 24 in FIGS. 2-4), which are cut to specific lengths in order to deliver specific frequencies to the atomic magnetometers. The length of the cables is dependent on the width of the attenuation tube and also the frequencies to be attenuated. The shielding 2402, attenuation tubes and other elements form a shielding structure that encloses the atomic magnetometers, sample, and Helmholtz coils. The shielding 2402 enclosure that includes the Faraday cage with a layer of Mu metal on all sides including top and bottom. The shielding enclosure forms a container that may be round or spherical, which may provide for greater attenuation, although other shapes are of course possible. As mentioned previously, the detector operates only with small magnetic fields and thus has a high sensitivity level. The thickness of materials, and/or the number of layers, in the shielding may be adjusted based on particular applications of the MIDS device. For example, for samples producing lower levels of magnetic fields, improved attenuation may be necessary to detect signals at those levels.

In one embodiment, a sample 2404 may be lowered in from the top of the shielding enclosure, between or adjacent to at least two miniaturized magnetometers or detectors 2406 and 2408. Alternatively the system could be built to allow horizontal access (e.g. like FIG. 2 above), or be configured in any other way. (The terms “detector” and “magnetometers” are generally used interchangeably.) Importantly, the spacing between the sample and first detector 2406, and spacing between the first and second detectors 2406 and 2408 may be selected to tune or optimize the system based on the sample or particular application to which the system is to be used. For example, with detectors having outside diameters of 2 cm allows for a first derivative gradiometer with a spacing of 3.2 cm. Magnetic fields of the sample would be closely coupled to at least one detector. Two magnetometers connected together and separated a particular distance from each other can form a gradiometer. The two magnetometers are operated in opposition and, if sensing the same precise field, should cancel each other out (e.g., if no field is present). In practice, one of the magnetometers is closely coupled to the target source (sample), while the other is loosely coupled to the target source. Yet both magnetometers are equally sensing the background environment. When the output of the target magnetometer is summed with the inverted output of the background magnetometer, the background is cancelled, leaving only the target source (signal) to be detected.

While the detectors 2406 and 2408 are not coils, the ratios for separation between detectors and coils would be roughly the same. The diameter of gradiometer coils and the distance between coils is adjusted or calculated to optimize the signal-to-noise ratio. These are called gradiometer baseline calculations and are dependent on the radius and area of each coil element (See, e.g., “Baseline Distance Optimization for SQUID Gradiometers; Alexander Garachtchenko, Applied Materials, Santa Clara Calif., USA; Andrei Matlashov, Robert H. Kraus, Jr., Los Alamos National Laboratory, Los Alamos N. Mex., USA”). For round coils a typical separation distance is 1.6 times the radius (for two identical coil elements). The distance increases as the ‘environmental element’ diameter increases.

A pair of Helmholtz coils 2420 and 2422 inject noise into the system, as described above. The system uses stochastic resonance to elevate a sub threshold signal to detectable levels. A coil pair (coils 2420 and 2422) is used to produce random noise for the purpose of generating stochastic resonance between the injected noise and a sub threshold weak signal. The noise and signal sum in such a way that elevates weak signal components above a detection threshold, allowing for those signals to be detected via magnetometers with high sensitivity. Altering the gradient characteristics of the field influences how point charge might be disturbed around the target molecule in solution, and also affects the generation of current in the individual gradiometer coil elements. Changing the field characteristics impacts how the source field is produced while also changing the noise cancellation dynamics of the gradiometer. Both of these parameters have an impact on the signal to noise ratio of the detected signal. For example, if the noise is not sufficiently attenuated by the gradiometers, the low level signal may not be detected over a necessary threshold.

White noise can also be applied using a Helmholtz coil pair 2420, 2422 that produces a noise field uniformly coupled to both magnetometer elements of the gradiometer. White noise can be used to produce stochastic resonance, elevating a sub threshold signal to detectable levels. The stochastic product will be most evident in the first magnetometer, allowing for a further improvement in the signal to noise ratio as the injected noise is cancelled within the gradiometer.

Each of the two detectors 2406 and 2408 include corresponding fiber optic cables 2410 that direct infrared laser light into a vapor cell that contains rubidium gas atoms. Each cell may include a light diffuser 2412, and light sensors 2414 coupled to fiber optic output cables 2416. An example of such a single magnetometer detector is described as a room temperature molecular magnetic field detector in U.S. Patent Application 2011/0031969 A1, Atomic Magnetometer and Method of Sensing Magnetic Fields; Kitching, et al, assigned to NIST. The detector uses laser light to heat a material vapor whose dynamics change in the presence of a magnetic field. The same, or a second laser light, is used to observe differences in absorption or light scattering as magnetic fields alter the dynamics of the vapor cloud. A separate vapor heater can also be used rather than using laser heating. Another example is a high-bandwidth optical magnetometer described by Ricardo Jiménez-Martinez, W. Clark Griffith, Svenja Knappe, John Kitching, and Mark Prouty in the Journal of the Optical Society of America B|OPTICAL PHYSICS Vol. 29, lss. 12—Dec. 1, 2012 pp: 3398-3403 (Editor: Henry van Driel, JOSA B, Vol. 29, Issue 12, pp. 3398-3403 (2012)).

In general, the energetic dynamics of biologic systems allows for perturbation of the magnetic environment through the movement of charge as described by Maxwell. For example, protein dynamics force the movement of not only point charge associated with hinging events, but also the transfer of charge along charge pathways. The ability to observe the magnetic perturbations in the wake of charge movement can be diagnostic of materials under measurement.

The system uses two miniature magnetometers that may be in a first or second derivative configuration for noise reduction. A first order gradiometer is two detectors measuring the difference between the target source detector 2406 (proximate to the sample) and an inverted background signal of the adjacent detector 2408 (i.e., adjacent to the other detector). If an additional set of detectors is added, this measures a second degree reading of the difference between a second target source detector 2426 and an inverted background signal of a second adjacent detector 2428, making a second iteration of the reading. Again, in order for the results to be utilized as first and second order, the spacing between the magnetometers, the gradiometers (e.g., sets of magnetometers) and the sample are equivalent. With a second order system, the sample signal variance, e.g., signal detected from the target source detector is more accurate. Thus, as an alternative configuration, the system may include a second derivative gradiometer to provide greater attenuation. This second derivative gradiometer includes two more magnetometers or detectors 2426 and 2428 oriented to the opposite side of the sample, in mirror image to the original pair (shown schematically in dashed lines).

Change in light absorption or scattering from each magnetometer is measured by a photo sensor that outputs a voltage relational to the number of photons detected. Each magnetometer in the first or second derivative configuration senses the environment at the same instant, and the output of each magnetometer is in phase with the other.

To accomplish noise reduction, one magnetometer is closely coupled (via magnetic fields) to a material under measurement (detector 2406), while a second magnetometer is placed at a distance from the sample (detector 2408). Because the first magnetometer is more closely coupled to the sample, any magnetic field related to the sample will have a greater inductive coupling to it than to the second magnetometer. However, each magnetometer will have equal coupling to fields in the background environment.

The phase of the output voltage of the second magnetometer (detector 2408) may be electronically inverted such that the phase of the second magnetometer is 180 degrees out of phase with the first (detector 2406). The two voltage outputs are then summed, effectively canceling any voltage that was the product of environmental noise. The remaining voltage is relational to the sample and is stored as time series data for future processing.

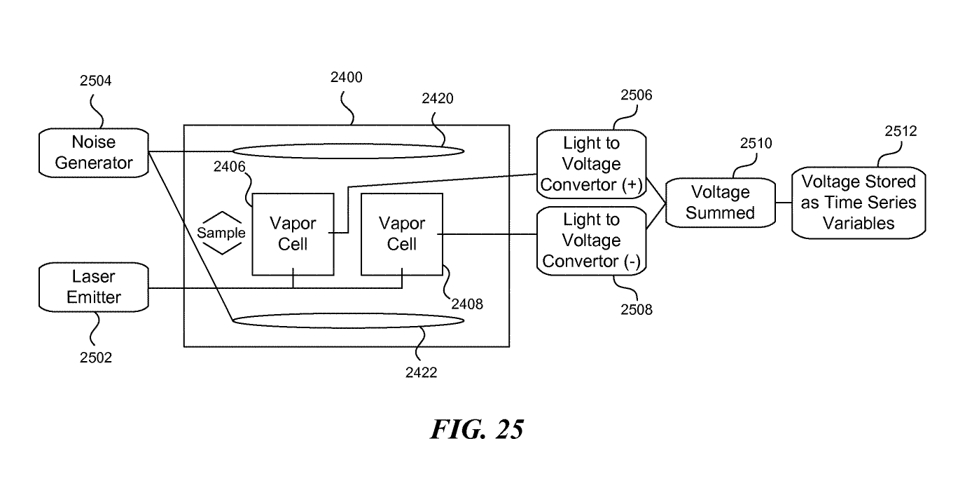

Referring to FIG. 25, an example of a system having a laser emitter 2502 providing light to detectors 2406 and 2408. A noise generator 2504, such as an General Radio Model 1381 Random Noise Generator, provides a controlled amount of noise to Helmholtz coils 2420 and 2422 in order to inject noise in the form of a magnetic field, into the shielded system. A first light to voltage converter 2506 receives the output from the first detector 2406, while a second light to voltage converter 2508 receive the output from the second detector 2408. Outputs from the converters are summed by a voltage summer 2510, whose output is then stored as a time series as noted above (shown as block 2512). The acquired data can be stored and processed using a variety of signal analysis techniques including spectral correlation, wavelets, Eigen analysis, and more, and is diagnostic of the material under study.

In general, entropy can be used to indirectly determine changes in the signal to noise ratio of a detected signal and coil alignment. A variety of mathematical solutions can be applied in real time or in post processing to determine entropy at the output of the detector. A typical method for measuring signal entropy is to observe how signal energy is distributed across a bandwidth. Energy that deviates from a Gaussian distribution is thought to have lower entropy than a purely random event.

A variety of spectral algorithms are useful in determining entropy including spectral auto correlations, Fourier analysis, wavelet analysis, and Eigen analysis. Adjustments to the orientation of the noise coil pair are made until a maximum negative deviation in entropy is observed at the output of the detector. If the analysis is being performed in real time adjustments can be made quickly and could be automated.

Adjustments can be made with respect to the noise coils. FIGS. 13A through 13F show examples of various coil arrangements or geometries to produce differing responses in system. Position-adjustable coils allows the coils to move from a Helmholtz configuration to other conformations. Each coil could be independently repositioned as indicated in the applicants other patents and applications to produce fields with varying gradients and vectors.

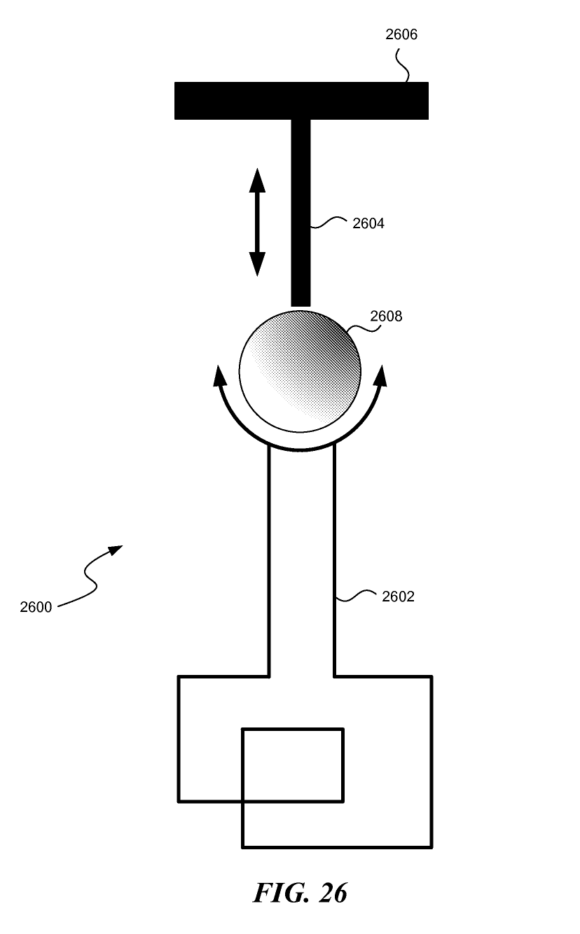

FIG. 26 shows an example of a system 2600 for adjusting a coil 2602. The coil 2602 maybe a Helmholtz coil, other coils discussed herein, or even the detectors 2406 and 2408. A telescoping arm 2604 is positioned between a base or frame 2606 and a gimbaled or ball joint 2608. The telescoping arm 2604 may include a servomotor or other electromechanical adjustment (not shown) to adjustably move the arm along one axis. The joint 2608 allows the coil 2602 to be rotated. Again another motor may be used to electromechanical move the coil about the joint.

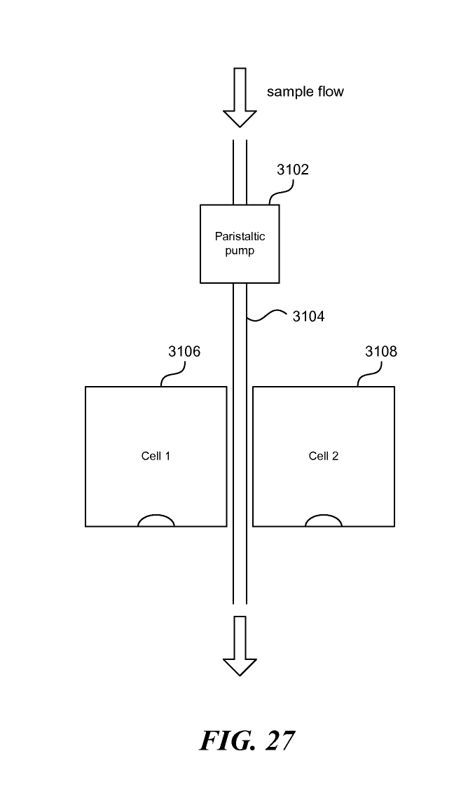

FIG. 27 illustrates an optical magnetometer flow through configuration of a gradiometer made from two atomic magnetometers and divided by an optical flow tube in one embodiment. In this configuration, the gas chambers, or cells 3106 and 3108, within each magnetometer are uniformly optically pumped with a sample. The pump can be a parasitic pump coupled to an optical flow tube which extends between each magnetometer. A sample is pumped by a parasitic pump 3102 between the magnetometers 3106 and 3108 for a specified time interval over which measurements are taken from the light detectors located within each gas cell, similar to that described with reference to FIG. 24. The cells of the magnetometers 3106 and 3108 can be closely spaced in order for optimal coupling to the flow tube 3104 and sample. New samples can be pumped after each time interval elapses. Further, stepper motors, not shown, could move the magnetometers 3106 and 3108 closer or further from the tube.

While not shown, the system may include a phase shifter, appropriate amplification, etc. The system may employ a DC offset, with the injected noise.

Many alternatives are, of course, possible. For example, several detectors may be arranged in a plane, such as in a cross arrangement. A tube or port may be provided at the center of the detectors, through which sample may be transported. Thus, a material may flow through the tube and be detected by the detectors, thereby permitting a higher rate detection of a stream of samples.

In another alternative, detectors may be placed in X, Y and Z axes, to thereby form a three-dimensional array of detectors. A sample may be placed in the center of the detectors and a detection made along the X, Y and Z axes. This alternative allows a sample to be analyzed in three dimensions, and thus the geometry or model of the sample, at a molecular level, maybe detected.

One benefit of the above embodiments is that the detectors are effective at room temperature, and thus a sample may be measured over a long period of time, where prior samples would typically be subjected to an extremely cold environment and thus could not withstand such cold for a long period of time. Prior systems required a heater, which can be avoided here. Many other advantages and benefits of the system are of course recognizable by those of ordinary skill in the art.

### CONCLUSION

Further details regarding aspects of the system may be found in the commonly owned U.S. Pat. Nos. 6,724,188, 6,995,558, 6,952,652, 7,081,747, 7,412,340, and 7,575,934, each of which is incorporated herein by reference in its entirety.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

All of the above patents and applications and other references, including any that may be listed in accompanying filing papers, are incorporated herein by reference. Aspects of the invention can be modified, if necessary, to employ the systems, functions, and concepts of the various references described above to provide yet further embodiments of the invention.

These and other changes can be made to the invention in light of the above Detailed Description. While the above description details certain embodiments of the invention and describes the best mode contemplated, no matter how detailed the above appears in text, the invention can be practiced in many ways. Details of the signal processing system may vary considerably in its implementation details, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

We claim:

1. An apparatus for analyzing molecular signals produced from a sample, the apparatus comprising:
(a) a signal source holder configured to hold the sample;
(b) two or more miniaturized magnetometers including a vapor chamber filled with gas atoms,
wherein the magnetometers are capable of detecting magnetic fields produced by the sample,
wherein a first magnetometer is positioned adjacent to a second magnetometer, and
wherein at least one magnetometer is proximate to the signal source holder and the sample;
(c) a coil configured to uniformly produce noise surrounding the sample and the magnetometers, wherein the noise produced is capable of inducing stochastic resonance in the sample to amplify the sample characteristic signals;
(d) at least one magnetic shield for electromagnetically shielding the signal source and the magnetometers from external electromagnetic radiation; and
(e) at least one opening in the magnetic shield capable of receiving two or more optical cables,
wherein each of the two or more miniaturized magnetometers are coupled to one or more cables,
wherein at least one cable is utilized for transmitting light/radiation to the magnetometers, and
wherein at least one cable is cable is capable of receiving light/radiation from the magnetometers.

2. The apparatus of claim 1, further comprising a layer of Mu metal alloy coating the magnetic shield.

3. The apparatus of claim 1, further comprising a second opening in the magnetic shield capable of receiving an electrical cable configured to deliver an electrical current to the coil.

4. The apparatus of claim 1, wherein the magnetometers are configured in a first derivative configuration in which the first magnetometer is proximate to the sample and the second magnetometer is adjacent to the first magnetometer in a first derivative configuration.

5. The apparatus of claim 1, wherein the magnetometers are configured in a second derivative configuration in which a first set of magnetometers is equally positioned on differing sides of the sample, each set having a first magnetometer proximate to the sample and a second magnetometer adjacent to the first magnetometer.

6. The apparatus of claim 1, further comprising an attenuation tube coupled to the at least one side opening and external to the magnetic shield, wherein the attenuation tube is electrically coupled to the magnetic shield.

7. The apparatus of claim 1, wherein each of the magnetometers is coupled to an optical cable capable of receiving light radiation output from light detectors.

8. The apparatus of claim 1, wherein the coil is a Helmholtz coil, and wherein the coil is coupled to a moveable frame.

9. The apparatus of claim 1 wherein the signal source holder is a tube, and wherein the apparatus further comprises a peristaltic pump to move multiple samples through the tube and past the two or more miniaturized magnetometers.

10. A system for analyzing signals produced from a sample, the system comprising:
at least a first magnetometer,
wherein the first magnetometer is capable of detecting magnetic fields produced by a sample,
wherein the first magnetometer is positioned proximate to the sample; and,
wherein the first magnetometer has a size less than 6 cm per side;
a noise producing component configured to uniformly produce noise surrounding the sample and the first magnetometer,
wherein the noise produced is capable of inducing stochastic resonance in the sample to amplify characteristic signals of the sample; and,
at least one shielding structure for electromagnetically shielding the sample and the first magnetometer from external electromagnetic radiation.

11. The system of claim 10, further comprising:
at least one opening in the magnetic shield capable of receiving cables,
wherein the first magnetometer is coupled to the cables,
wherein at least one cable is utilized for transmitting light/radiation to the magnetometer, and
wherein at least one cable is cable is capable of receiving light/radiation from the magnetometer, and
wherein at least one of the cables has a length to attenuate unwanted frequencies in received signals.

12. The system of claim 10, further comprising a layer of Mu metal alloy coating the shielding structure.

13. The system of claim 10, further comprising an opening in the shielding structure capable of receiving an electrical cable configured to deliver an electrical current to the coil.

14. The system of claim 10, wherein multiple magnetometers are configured in a first derivative configuration in which the first magnetometer is proximate to the sample and a second magnetometer is adjacent to the first magnetometer in a first derivative configuration.

15. The system of claim 10, wherein multiple magnetometers are configured in a second derivative configuration in which a first set of magnetometers is equally positioned on differing sides of the sample, each set having a first magnetometer proximate to the sample and a second magnetometer adjacent to the first magnetometer.

16. The system of claim 10, further comprising an attenuation tube coupled to the at least one side opening and external to the shielding structure, wherein the attenuation tube is electrically coupled to the shielding structure.

17. The system of claim 10, wherein the first magnetometer includes a vapor chamber filled with gas atoms, and is coupled to an optical cable capable of receiving light radiation output from light detectors.

18. The system of claim 10, wherein the noise producing component includes a Helmholtz coil, and wherein the coil is coupled to a moveable frame.

19. A method for analyzing an effect of a chemical or biochemical agent on a system responsive to such agent, comprising:
providing a sample within a shielding structure and proximate to at least one magnetometer;
placing a sample containing the agent in a container having both magnetic and electromagnetic shielding, wherein the sample acts as a signal source for molecular signals;
injecting noise into the sample in the absence of another signal from another signal source at a noise amplitude sufficient to generate stochastic resonance, wherein the noise has a substantially uniform amplitude over multiple frequencies;
detecting output radiation from the sample and recording an electromagnetic time-domain signal composed of sample source radiation superimposed on the injected noise in the absence of the another generated signal, wherein the signal is obtained via at least one room-temperature, miniaturized magnetometer; and
repeating the injecting and detecting at each of multiple noise levels within a selected noise-level range if the sample source radiation is not sufficiently distinguishable from the injected noise until the superimposed signal takes on characteristics of the signal generated by the signal source through stochastic resonance;
identifying frequencies representing dominant characteristics of the time-domain signal;
synthesizing a response-producing signal by:
selecting at least one frequency from the identified frequencies of the sample; or
combining frequencies selected from the identified frequencies of two or more agent samples; and
exposing the agent-responsive system to the synthesized response-producing signal by placing the agent-responsive system within an electromagnetic or magnetic field of an electromagnetic transducer, and applying the synthesized signal by the transducer at a signal amplitude and for a period sufficient to produce in the agent-responsive system an agent-specific effect.

20. The method of claim 19, wherein the synthesized response-producing signal is a combination of:
the identified frequencies of one or more agent samples that represent chemical or biological effects of the sample; or
frequencies selected from identified frequencies of one or more agent samples that represent some aspects of chemical or biological effects of each agent sample.

21. The method of claim 19, wherein the analyzing is carried by one of:
(i) generating a histogram that shows, for each event bin f over a selected frequency range within a range DC to 8 kHz, a number of event counts in each bin, where f is a sampling rate for sampling the time domain signal, assigning to the histogram, a score related to number of bins that are above a given threshold; and selecting a time-domain signal based on the score;
(ii) autocorrelating the time domain signal, generating an FFT (Fast Fourier Transform) of the autocorrelated signal over a selected frequency range within the range DC to 8 kHz, assigning to the FFT signal a score related to a number of peaks above a mean average noise value, and selecting a time-domain signal based on the score; and
(iii) calculating a series of Fourier spectra of the time-domain signal over each of multiple defined time periods, in a selected frequency range between DC and 8 kHz, averaging the Fourier spectra; assigning to the averaged FFT signal a score related to the number of peaks above a mean average noise value, and selecting a time-domain signal based on the score.

22. The method of claim 19, wherein the electromagnet transducer includes either one or both of an implantable coil that is implanted in a biological system prior to the exposing and a hand-held mobile device, wherein signals arrive at the transducer via wire or wireless communication, and wherein wireless signals are transmitted directly or via satellite.
